(19) United States
(12) Patent Application Publication
(10) Pub. No.: US 2010/0299575 A1
(43) Pub. Date: Nov. 25, 2010

(54) METHOD AND SYSTEM FOR DETECTION AND CORRECTION OF PHASED-BURST ERRORS, ERASURES, SYMBOL ERRORS, AND BIT ERRORS IN A RECEIVED SYMBOL STRING

(75) Inventors: Ron M. Roth, Haifa (IL); Pascal O. Vontobel, Palo Alto, CA (US)

Correspondence Address: HEWLETT-PACKARD COMPANY;Intellectual Property Administration, 3404 E. Harmony Road, Mail Stop 35, FORT COLLINS, CO, 80528, US

(73) Assignee: Hewlett-Packard Development Company, L.P.

(21) Appl. No.: 12/864,233

(22) PCT Filed: Mar. 3, 2008
(86) PCT No.: PCT/US08/02836

§ 371 Date: Jul. 22, 2010

(30) Foreign Application Priority Data
Feb. 14, 2008 (US) 12/070074

(51) Int. Cl. H03M 13/29; G06F 11/10

(52) U.S. Cl. 714/755; 714/E11.032

(57) ABSTRACT

Embodiments of the present invention include ECC-based encoding-and-decoding schemes that are well suited for correcting phased bursts of errors or erasures as well as additional symbol errors and bit errors. Each encoding-and-decoding scheme that represents an embodiment of the present invention is constructed from two or more component error-correcting codes and a mapping function ƒ(). The composite error-correcting codes that represent embodiments of the present invention can correct longer phased bursts or a greater number of erasures in addition to single-bit errors and symbol errors, respectively, than either of the component codes alone, and are more efficient than previously developed ECC-based encoding-and-decoding schemes for correcting phased bursts of symbol errors and erasures combined with additional bit errors and symbol errors.

### TECHNICAL FIELD

The present invention is related to correction of errors or erasures that occur in symbol strings passed through an error-and-erasure-introducing channel, including electronic transmission of the symbol string or storage of the symbol strings in, and retrieval of the symbol strings from, an electronic memory.

### BACKGROUND OF THE INVENTION

The field of error-correcting codes (“ECCs”) has been well studied and researched for over 50 years. Many different types of encoding-and-decoding schemes based on error-correcting codes have been developed for application to many different problem domains. ECC-based encoding-and-decoding schemes generally involve introduction of redundant information into an encoded information stream to allow various types of errors subsequently introduced in the information stream to be detected and corrected. As with most computational techniques, there are a variety of advantages, disadvantages, efficiencies, and inefficiencies associated with any particular encoding-and-decoding scheme applied to any particular problem domain. For example, as the amount of redundant information added to an information stream increases, the quantities and types of errors that can be detected and corrected within the information stream generally increases, but the information, or space, efficiency of transmission of the information stream decreases due to the increasing overhead of the redundant information. Space inefficiencies can also result from the need to create and maintain large amounts of data needed for encoding or decoding, such as decoding tables, discussed below. As another example, a symbol efficient code may involve complex computation, and may therefore be computationally, or time, inefficient. The overall efficiency of a code is related to the sum of the space and time efficiencies of the code, but space efficiency is often obtained at the expense of time efficiency, and vice versa. Certain types of ECC-based encoding-and-decoding schemes are better suited to detecting and correcting certain types of errors, and may be less well suited for detecting and correcting other types of errors. As new problem domains are recognized, or as new problem domains emerge as a result of the development of new types of technologies, continued development of new ECCs and ECC-based encoding-and-decoding schemes well suited for the newly recognized problem domains or newly developed technologies are needed in order to provide for efficient and accurate error detection and correction.

### SUMMARY OF THE INVENTION

Embodiments of the present invention include ECC-based encoding-and-decoding schemes that are well suited for correcting phased bursts of errors or erasures as well as additional symbol errors and bit errors. Each encoding-and-decoding scheme that represents an embodiment of the present invention is constructed from two or more component error-correcting codes and a mapping function ƒ(). The composite error-correcting codes that represent embodiments of the present invention can correct longer phased bursts or a greater number of erasures in addition to single-bit errors and symbol errors, respectively, than either of the component codes alone, and are more efficient than previously developed ECC-based encoding-and-decoding schemes for correcting phased bursts of symbol errors and erasures combined with additional bit errors and symbol errors.

According to one embodiment of the present invention, encoding of information into a composite-code codeword is carried out by receiving K, information symbols and encoding the K, information symbols by a first component code C₁ encoder to produce a C₁ codeword u of length N₁ symbols. Then, K₂ information symbols are encoded by a second component code C₂ encoder to produce a codeword v of length N₂. A vector w of length N₂ symbols is obtained by adding a non-identity mapping of u, ƒ(u), to v. Finally, a composite-code-C codeword is generated by concatenating u and w together.

According to one embodiment of the present invention, decoding of a composite-code codeword is carried out by decoding component-code codewords. A component-code-C₁ codeword u of length N₁ containing K₁ information symbols and a modified component-code-C₂ codeword of length N₂, w=v+ƒ(u), generated, during encoding, from a component-code-C₂ codeword v containing K₂ information symbols, where K=K₁+K₂ and N=N₁+N₂, and a non-identity mapping function, ƒ(), are extracted from a composite-code-C codeword. An estimated component-code-C₂ codeword \hat{v} and an estimated error word ê are then generated from the modified component-code-C₂ codeword by applying a C₂ decoder to the modified component-code-C₂ codeword. Which of a number of types of expected errors that may occur subsequent to encoding of the composite-code-C codeword is determined from the error word ê. When more than a first threshold number of erasures and erasures have occurred, but less than a second threshold number of errors have occurred, the determined errors are assigned to either the component-code-C₁ codeword or to the modified component-code-C₂ codeword, and when assigned to the component-code-C₁ codeword, are corrected. Other error and erasure occurrences are marked. An estimated component-code-C₁ codeword û is obtained by applying a C₁ decoder to the estimated component-code-C₁ codeword û. Finally, K₁ information symbols are extracted from the estimated component-code-C₁ codeword û and K₂ information symbols are extracted from the estimated component-code-C₂ codeword \hat{v} to produce K extracted information symbols.

### BRIEF DESCRIPTION OF THE DRAWINGS

FIG. 1 illustrates a basic problem to which ECC-based encoding-and-decoding schemes are applied.

FIG. 2 illustrates various different views of a digitally encoded information stream.

FIG. 3A illustrates the vector space V of all possible codewords produced by a systematic linear block code that encodes information into codewords of length n.

FIG. 3B shows an exemplary code, or vector subspace, of the vector space V shown in FIG. 3A.

FIG. 4 shows the distance between any two codewords v and w, D(v,w).

FIG. 5 illustrates encoding and transmission of a vector u of k information bits by a systematic linear block code.

FIG. 6 illustrates encoding of the information-bit vector u to produce codeword v, as discussed with reference to FIG. 5.

FIGS. 7A-B show an exemplary systematic generator matrix G and an exemplary systematic parity-check matrix H for a systematic linear block code.

FIG. 8 shows a property of the transpose of the parity-check matrix, H^{T.}

FIG. 9 illustrates a portion of the decoding process for a systematic linear block code.

FIG. 10 illustrates a decoding table that can be constructed for any systematic linear block code over GF(2).

FIG. 11 shows a portion of the table of elements for GF(2⁸).

FIG. 12 illustrates the basic characteristics of a composite code that represents one embodiment of the present invention.

FIG. 13 illustrates the characteristics of the symbol-to-symbol mapping function ƒ() used in embodiments of the present invention.

FIG. 14 shows two different implementations of the symbol-to-symbol mapping function ƒ().

FIG. 15A provides a high-level control-flow diagram for encoding of information bits into a composite-code codeword according to one embodiment of the present invention.

FIG. 15B illustrates construction of the composite code C[72,66,5] that represents one embodiment of the present invention.

FIG. 16 illustrates a method of encoding a composite-code codeword that can be carried out repeatedly on an input stream of information symbols to produce an output stream of composite-code codewords.

FIG. 17A illustrates the notion of a sub-block within a codeword of the composite code that represents one embodiment of the present invention.

FIG. 17B illustrates the various different types of errors that the composite code that represents one embodiment of the present invention is designed to detect and correct.

FIG. 18 provides a high-level control-flow diagram for decoding of a composite code that represents one embodiment of the present invention.

FIGS. 19-20 provide a control-flow diagram that illustrates one embodiment of the decoding process for composite codes that represent embodiments of the present invention.

FIG. 21 illustrates the information received for each step of a decoding method for the composite code that represents one embodiment of the present invention.

FIG. 22 shows a block diagram of a physical memory device in which embodiments of the present invention may be employed.

FIG. 23 illustrates mapping between codeword symbols and DRAM units in a bank of DRAM units that together comprise the electronic data storage component of the physical memory device illustrated in FIG. 22.

### DETAILED DESCRIPTION OF THE INVENTION

The present invention is directed to error-correcting codes (“ECCs”) and ECC-based encoding-and-decoding schemes well suited for detecting and correcting phased bursts of symbol errors and/or erasures and additional single-bit errors and symbol errors, respectively, in a symbol string passed through an erasure-and-error-introducing channel. The present invention is discussed, below, in three subsections. In a first subsection, an overview of one family of error-correcting codes is provided. These error-correcting codes are examples of component ECCs that may be used to construct the composite ECCs that represent embodiments of the present invention, although many additional types of ECCs may be used as components for the composite ECCs. In a following subsection, a brief summary of groups and fields is provided. Finally, in a third subsection, composite codes and composite-code-based encoding-and-decoding schemes to which the present invention is directed are described, with detailed descriptions of encoding and decoding methods for one disclosed composite code.

### Systematic Linear Block Codes

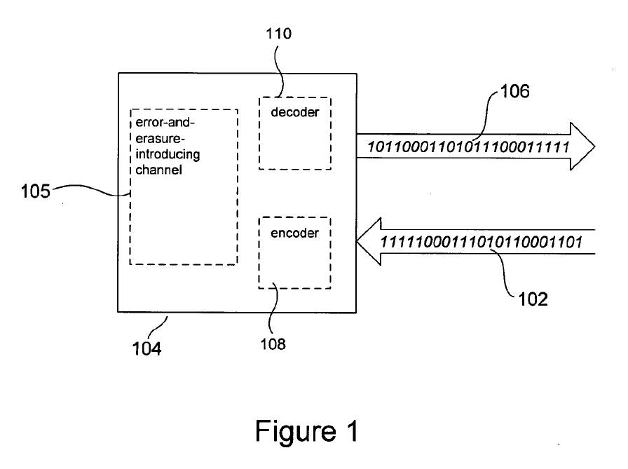

FIG. 1 illustrates a basic problem to which ECC-based encoding-and-decoding schemes are applied. In FIG. 1, a binary-encoded information stream 102 is input to a memory, communications system, or other electronic device, subsystem, or system 104 that exhibits characteristics of an error-introducing channel 105. Subsequently, the digitally encoded information stream is extracted 106 from the memory, communications system, or other electronic device, subsystem, or system 104. It is desirable, and generally necessary, that the extracted information stream 106 be identical to the originally input information stream 102. In order to achieve error-free recovery of information input to the memory, communications system, or other electronic device, subsystem, or system 104, an encoder 108 can be used to introduce redundant information into the information stream and decoder 110 can be used to employ the redundant information to detect and correct any errors introduced by the error-introducing-channel characteristics of the memory, communications system, or other electronic device, subsystem, or system 104. In FIG. 1, the binary-encoded information stream is represented in a left-to-right direction 102 when input and in a right-to-left direction when extracted 106. However, in general discussions of ECC-based encoding-and-decoding schemes, an encoded information stream is generally represented in left-to-right order, regardless of whether the information stream represents an input information stream or a received information stream, with the understanding that encoded information is generally transmitted sequentially, bit-by-bit, or byte-by-byte, and then reassembled on reception.

Error-introducing-channel characteristics may be exhibited by an electronic communications medium, such as a fiber-optic cable with a transmitting port on one end and a receiving port at the other end, an Ethernet link with Ethernet ports and controllers included in computing devices that are connected by the Ethernet link, and in other familiar electronic-communications media. Alternatively, error-introducing-channel characteristics may be exhibited by an information-storage device or component, including different types of electric memories, a mass-storage device, or a physical data-storage medium, such as a DVD or CD. In the case of a communications medium, an information stream initially input to a transmission port may be subsequently received as a corrupted information stream by a receiving port, with errors introduced into the information stream by port-processing components, noise in the transmission medium, and other such error-introducing phenomena. In the case of a storage medium, an initial information stream input to the storage medium may be subsequently retrieved from the storage medium in a corrupted form, with errors introduced into the information stream by storage-component controllers and other processing components, by noise and transmission media, and by electronic, magnetic, and/or optical instabilities in the storage media.

There are various types of errors that may corrupt an encoded information stream. Random bit or symbol errors may result in alteration of the bit or symbol values of certain bits and symbols in the information stream, with the bits or symbols in the information stream having a known or estimable probability of corruption. Burst errors result in corruption in runs of adjacent bits and/or symbols. Many different types of systematic errors, in addition to burst errors, may also occur.

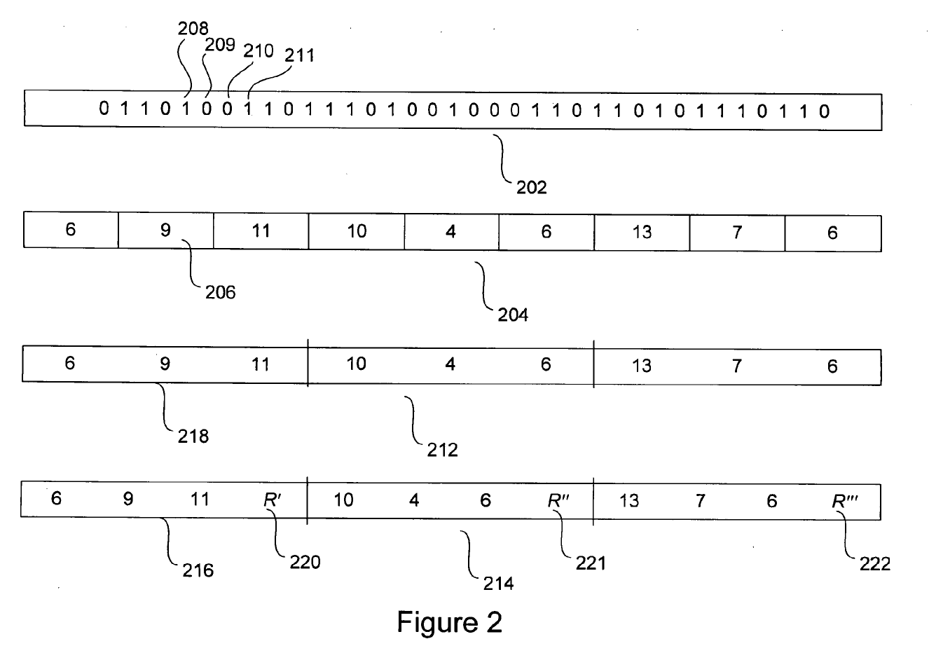

FIG. 2 illustrates various different views of a digitally encoded information stream. A digitally encoded information stream can be viewed as an ordered sequence of bit values, or, in other words, the information stream comprises a long, linear array of bit values. Alternatively, the same encoded information stream can be viewed as the ordered sequence of symbols, each symbol comprising a fixed number of bit values. For example, in FIG. 2, the binary encoded information stream 202 can be alternately viewed as an ordered sequence of four-bit symbols 204. The value “9” shown in FIG. 2 for the second symbol 206 in the ordered sequence of symbols corresponds to the ordered set of bit values 208-211 in the bit-value representation of the encoded information stream 202. In yet another view, the encoded information stream may be viewed as an ordered sequence of blocks 212, each block including an ordered sequence of a fixed number of symbols. Finally, an information stream may be encoded, by a systematic linear block code, to include redundant information to allow for errors to be subsequently detected and corrected. The encoded information stream 214 comprises an ordered sequence of blocks, or codewords, each codeword corresponding to a block in the information stream. For example, the codeword 216 of the encoded information stream corresponds to the block of symbols 218 in the block-view of the information stream 212. Each codeword includes an additional symbol 220-222, represented in FIG. 2 by the characters R′, R″, and R′″. This extra symbol represents the redundant information included in the information stream by one type of systematic linear block code. In alternative types of linear block codes, each codeword may comprise a first, selected number of information symbols as well as a second selected number of additional symbols representing added redundant information, with the ratio of redundant information symbols to information symbols generally correlated with the number of errors or erasures that may be detected and the number of errors or erasures that may be corrected.

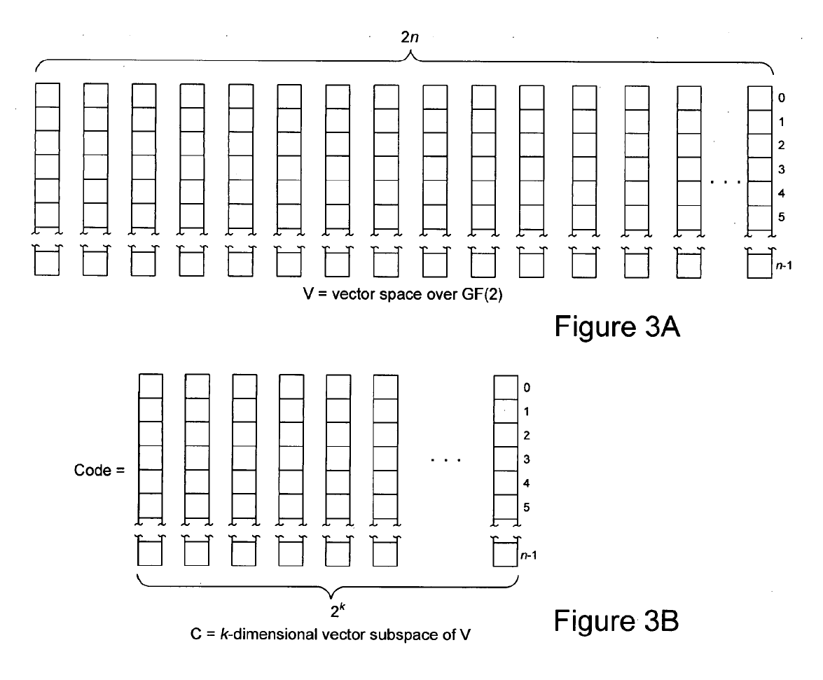

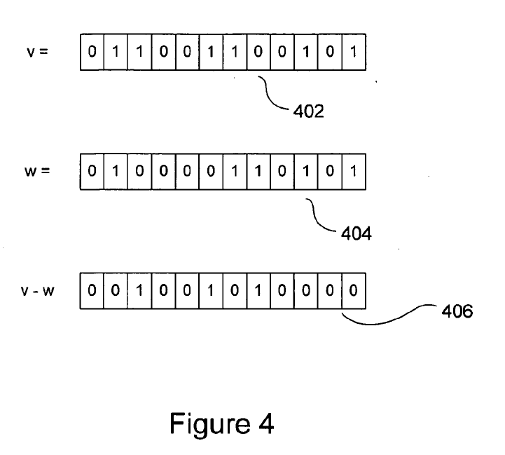

One commonly used type of ECC is a systematic linear block code over a finite field GF(q), where q represents the number of symbols in a field over which the code is defined. When q is a power of 2, 2^{m}, the symbols of the field are represented as m-tuples. When m is equal to 8, symbols are conveniently represented as bytes. The notation “GF(2)” stands for the binary Galois field with two elements, or symbols, “0” and “1.” Given a fixed number of bits in each encoded block, or codeword, produced by a systematic linear block code over GF(2), all of the possible codewords together comprise a vector space. A vector space has certain algebraic properties, including being commutative under addition, closure under scalar multiplication, and is distributive and associative with respect to vector addition and scalar multiplication of vectors. FIG. 3A illustrates the vector space V of all possible bit vectors of length n over GF(2). A particular systematic linear block code C that produces codewords of length n is a k-dimensional vector subspace of V, the vector subspace having all of the properties of a vector space. FIG. 3B shows an exemplary code, or vector subspace, of the vector space V shown in FIG. 3A. Each k-dimensional vector in the vector subspace represents k bits of information from an information stream. The k bits of information are supplemented, by the systematic linear block code, with r=n−k additional bits to produce a codeword. There is one particular pattern of r additional bits, or parity bits, for each different possible k-dimensional vector of information bits. Thus, a systematic linear block code comprises 2^{k} different n-bit vectors of the vector space V that constitute a vector subspace. For a systematic linear block code over GF(q), rather than bits, each vector containing n symbols, of which k symbols are information symbols and n−k symbols are redundant information used for detecting and correcting errors. The vector subspace comprising the codewords of the systematic linear block code over GF(q) contains q^{k} vectors.

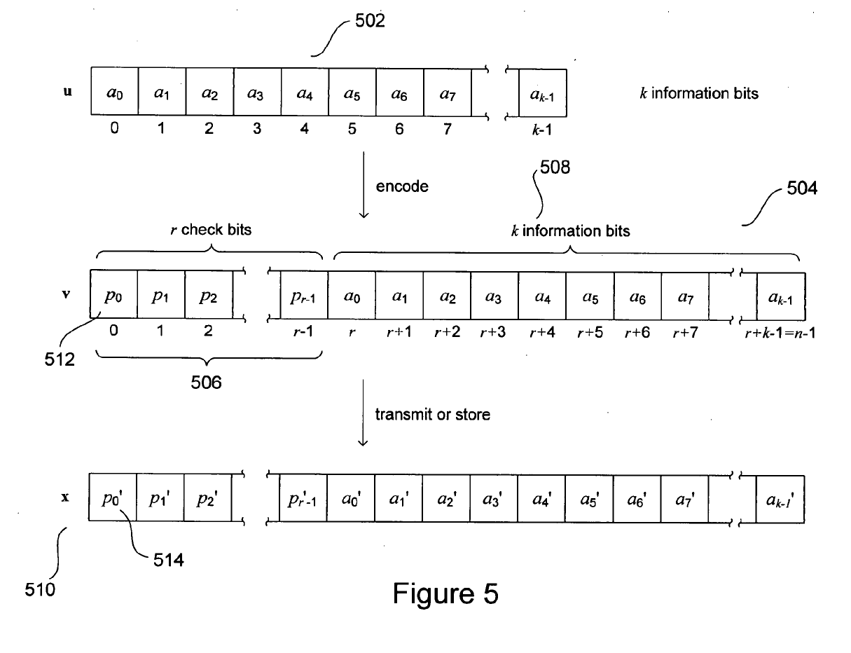

An important characteristic of an ECC is the minimal distance d between any two codewords of the code. FIG. 4 shows the distance between any two codewords v and w, D(v,w), of an ECC over GF(2). The vector v is a 12-bit codeword 402 and w is a second 12-bit codeword 404. Subtracting w from v by modulo 2 subtraction, equivalent to a bit-by-bit XOR operation, produces the difference between v and w, v−w, 406. In the case of an ECC over GF(2), the number of bits with bit value “1” in the vector v−w 406 is equal to the distance between v and w, D(v,w). In the general case of an ECC over GF(q), the number of non-zero positions in the difference vector v−w is the distance between the two codewords v and w. The weight of any particular codeword v, W(v), is the number of non-zero positions in the codeword. Thus, D(v,w)=W(v−w)=3 in the example shown in FIG. 4.

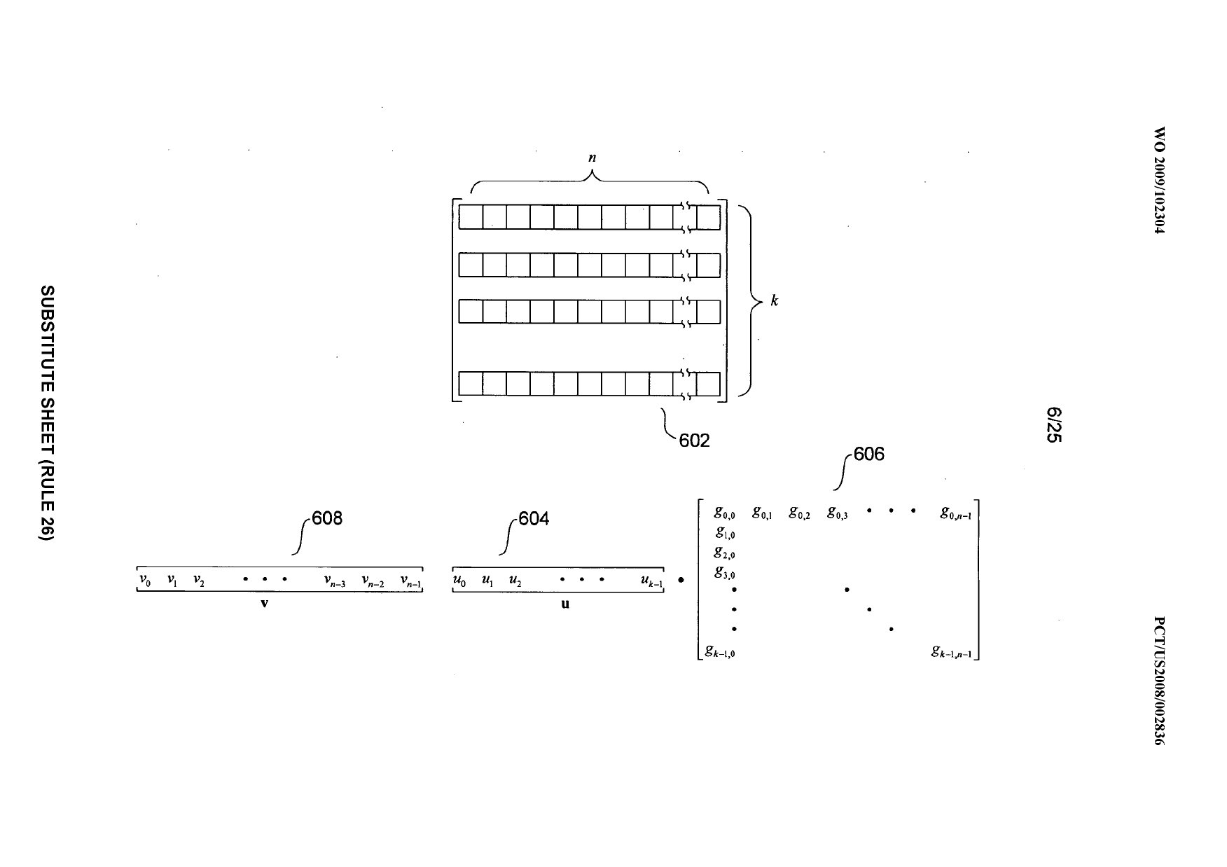

FIG. 5 illustrates encoding and transmission of a vector u of k information symbols by a q-ary systematic linear block code. The k information symbols are considered to be a k-dimensional vector u 502. A systematic linear block code encodes the k information symbols, represented by the vector u, as a vector v of length k+r=n 504. A systematic linear block code places r check symbols, or parity symbols, together in a subvector of vector v having length r, generally either at the beginning or the end of vector v. In the example shown in FIG. 5, and continued in subsequent figures, the parity symbols p₀, p₁, . . . , pᵣ₋₁ 506 are shown in the initial part of vector v, and the k information symbols 508 follow. The codeword v is then transmitted through a communications medium or stored to, and retrieved from, a storage medium to produce the corresponding received word x 510. When no errors occur in transmission or storage, x=v. However, when random transmission or storage errors occur, x≠v. In many cases, the recipient of the vector x cannot compare x with the initial, corresponding vector v in order to ascertain whether errors have or have not occurred. Therefore, the recipient of vector x assumes that each symbol, or bit, in x may have been corrupted with some probability of corruption. Therefore, the symbols in x are primed, in FIG. 5, to indicate that the symbols may have been corrupted with a known or estimable probability of corruption. Thus, symbol p₀ 512 in codeword v corresponds to symbol p₀ 514 in the received word x.

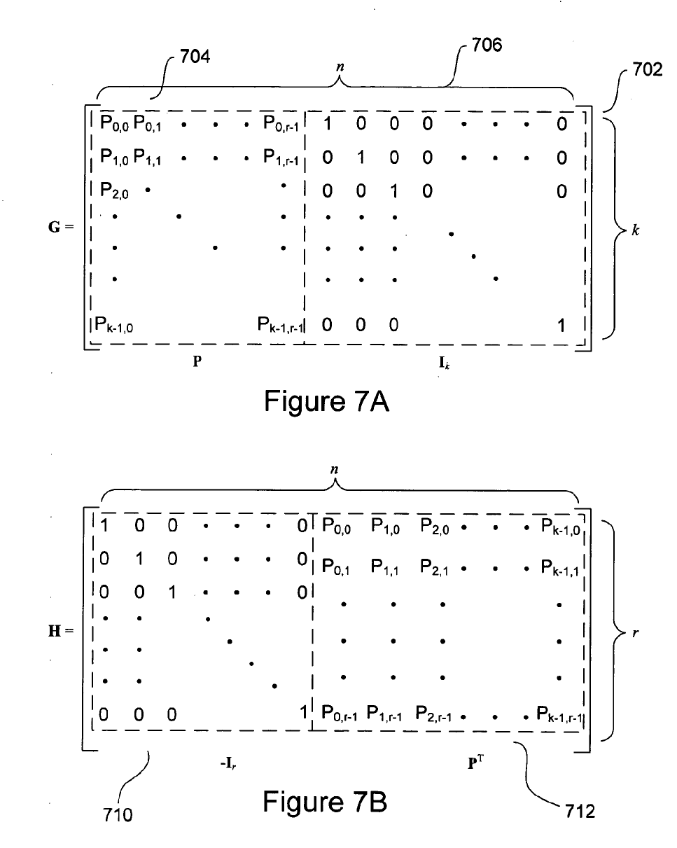

FIG. 6 illustrates encoding of the information-bit vector u to produce codeword v, as discussed with reference to FIG. 5. A k×n matrix G 602 can be found, for a given systematic linear block code, to generate a unique codeword v corresponding to each possible information-symbol vector u. As shown in FIG. 6, u 604 is multiplied by G 606 to produce the codeword v 608 corresponding to u. The matrix G is called a generator matrix for the systematic linear block code. The matrix G consists of k linearly independent codewords of the systematic linear block code C. Thus, codewords for systematic linear block codes are easily and mechanically generated from corresponding blocks of information symbols by matrix multiplication. In fact, each matrix G defines a systematic linear block code.

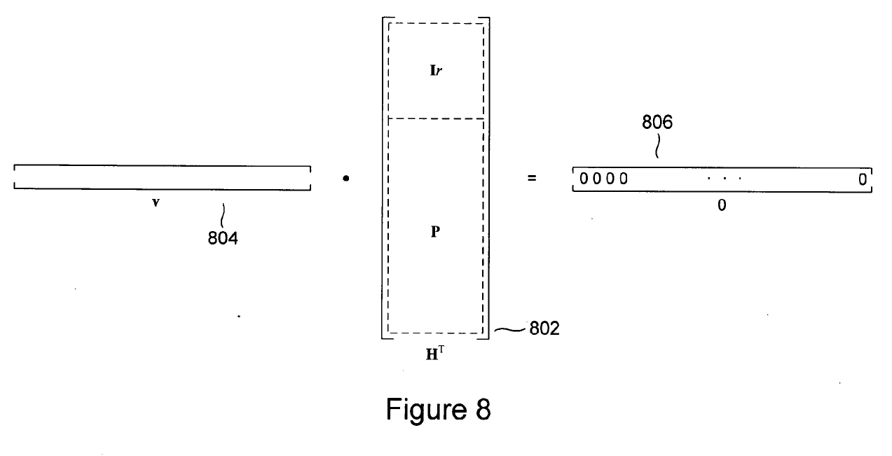

FIGS. 7A-B show an exemplary systematic generator matrix G and an exemplary systematic parity-check matrix H for a systematic linear block code. The generator matrix G 702, as shown in FIG. 7A, can be spatially partitioned into a parity-bit matrix P 704 of dimension k x r, and a k×k identity matrix Iₖ 706. The parity-bit matrix P, during matrix multiplication of u×G, generates the r parity symbols of v, and the identity matrix Iₖ 706 generates the k information symbols of u within the codeword v.

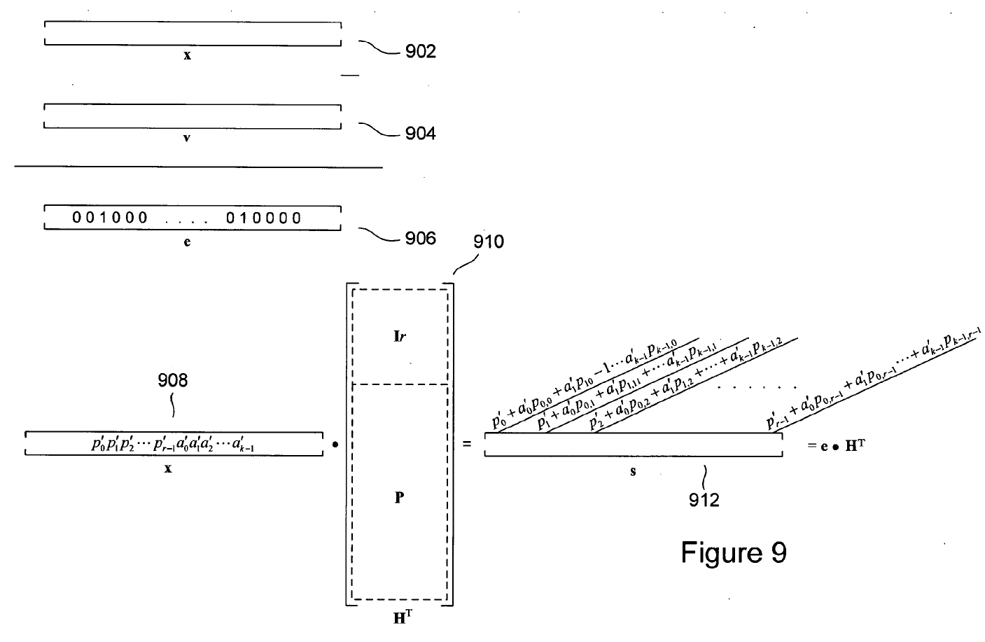

For each systematic linear block code, there is a parity-check matrix H corresponding to the generator matrix G. FIG. 7B illustrates the form of the parity-check matrix H. As can be seen in FIG. 7B, the parity-check matrix is an r×n matrix that can be spatially partitioned into an r×r identity matrix −Iᵣ 710 and the transpose of the parity-check matrix P^{T} 712. Any particular systematic linear block code is completely specified either by a generator matrix G or by the parity-check matrix H corresponding to the generator matrix G. The parity-check matrix H is itself a generator for a linear code, with each codeword including r information symbols. The linear code generated by the parity-check matrix is the dual code of the systematic linear block code C generated by the generator matrix G. FIG. 8 shows a property of the transpose of the parity-check matrix, H^{T}. As shown in FIG. 8, the transpose of the parity-check matrix, H^{T} 802, when used to multiply a codeword v of the systematic linear block code C, always generates the all-zero vector, 0, of dimension r 806. In other words, for each codeword v of systematic linear block code C:

v·H^{T}=0

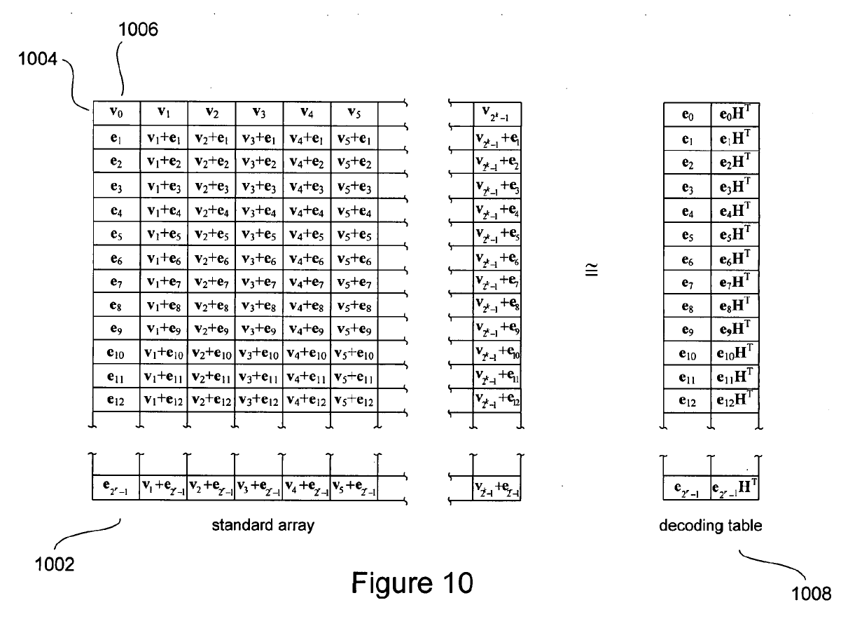

FIG. 9 illustrates a portion of the decoding process for a systematic linear block code. As discussed above, the received word x 902 may contain errors with respect to the corresponding, initially transmitted or stored codeword v 904. As discussed above, subtracting v from x, in the case that both v and x are known, produces a resultant vector 906 in which a non-additive-identity symbol (“1” in the case of GF(2)) appears at every position at which vectors x and v differ. Thus, x−v=e, where e is referred to as the “error vector,” essentially a map of occurred errors Of course, in general, only x is known. Thus, x equals v+e, where both v and e are generally unknown. Multiplication of the received word x 908 by the transpose of the parity-check matrix, H^{T}, 910, produces an r-dimension vector s 912 referred to as the “syndrome” of x. The syndrome of x is equal to e·H^{T}. Thus:

s=e·H^{T}=xH^{T}

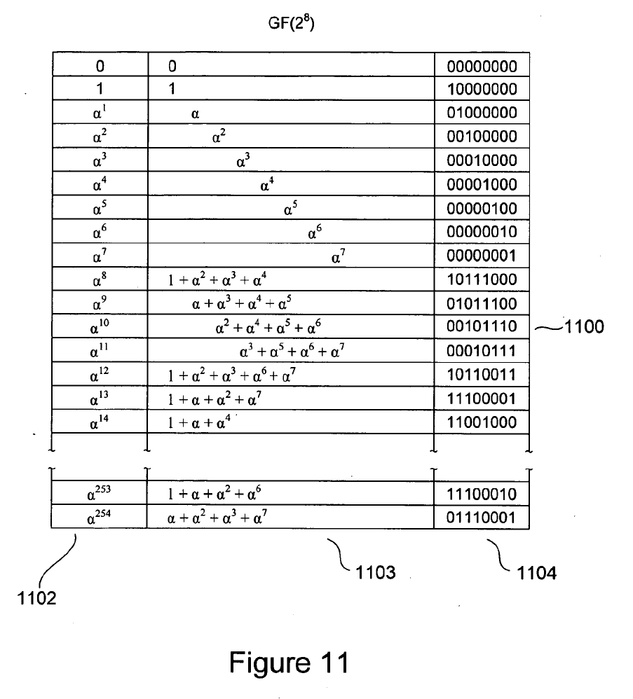

FIG. 10 illustrates a decoding table that can be constructed for any systematic linear block code over GF(q). As shown in FIG. 10, a q^{r}×q^{k} table, called the “standard array,” 1002 can be constructed for any systematic linear block code. The first row 1004 of the standard array is an ordered sequence of the codewords v₀, v₁, v₂, . . . , v_{q-1}^{k}. The codeword v₀ is the all-zero-symbol code vector (0, 0, . . . , 0). Each column i of the standard array can be considered to contain all possible received words xⱼ corresponding to the codeword vᵢ in the first element of the column. In other words, the set of all possible received words V has qⁿ elements, and is partitioned into q^{k} partitions, each partition corresponding to a codeword of the systematic linear block code C, with any received word x considered to correspond to the codeword associated with the partition of all possible codewords to which x belongs. For example, all of the elements of the first column 1006 of the standard array {e₁, e₂, . . . , e₂_{^{r}}₋₁} correspond to all possible error vectors that, when added to the all-zero codeword v₀, produce received words that are decoded to the all-zero codeword v_{0.}

As discussed with reference to FIG. 9, multiplication of a received word x by the transpose of the parity-check matrix H^{T} produces a syndrome vector s equal to e·H^{T}. The syndromes computed for all of the elements in each row of the standard array are therefore identical, depending only on e and H^{T}. Therefore, information contained in the standard array, for decoding purposes, can be compressed into a decoding table 1008 that shows the association between each recognized error pattern eᵢ and the syndrome corresponding to that error pattern eᵢH^{T}. Decoding of codewords of a systematic linear block code is, like encoding, carried out by a relatively conceptually simple process:

$$\begin{matrix}{s}_{x} = {xH}^{T} \\ \hat{e} = e in decoding table associated with {s}_{x} \\ \hat{v} = x + \hat{e}\end{matrix} \}$$

However, although conceptually simple, designing codes that can be efficiently decoded is a decidedly non-trivial task. Decoding tables, for example, are impractical for codes with medium and large q, r and/or n parameters, since the size of the decoding table 1008 is proportional to 2(q^{r})(n). Thus, great effort is generally undertaken to design codes with properties that allow for decoding algorithms that are both space and time efficient.

As can be seen in the standard array shown in FIG. 10, by increasing the number of parity symbols included in each codeword, a larger number of different error patterns may be recognized. However, as the ratio r/n increases, the space efficiency of encoding decreases. In general, the error patterns recognized by a systematic linear code are chosen to be the most probable error patterns. For random-bit errors, the error vectors with least weight are generally the most probable error patterns. For other types of errors, different sets of error patterns may be more probable.

While systematic linear block codes over GF(2) have been discussed, above, systematic linear block codes, including Reed-Solomon codes, can be analogously constructed over any field GF(q). Often, it is convenient to construct systematic linear block codes over extension fields of GF(2), generally specified as GF(2^{m}), where m is an integer greater than 1.

### Groups and Fields

In this subsection, an overview of groups and fields is provided. A group is a set of elements, over which a binary operation * is defined. The group is closed under the binary operation *. In other words, for any two elements of the group a₁ and a₂, a₁*a₂=aᵢ where aᵢ is also an element of the group. The binary operation * is associative, so that:

(a₁*a₂)*a₃=a₁*(a₂*a₃)

A group has a unique identity element e such that, for every element aᵢ in the group, there is an inverse element aᵢ⁻¹:

aᵢ*aᵢ⁻¹=aᵢ⁻¹*aᵢ=e

A group is commutative, or Abelian, when, for any pair of elements aᵢ and aⱼ:

aᵢ*aⱼ=aⱼ*aᵢ

A field is a commutative group with respect to two different binary operations. One operation may be denoted “+,” with the identity element for the operation +, e₊, equal to 0, and the other operation may be denoted “*,” with e*, the identity element for the operation *, equal to 1. Furthermore, the operation * is distributive:

a*(b+c)=a*b+a*c

GF(2) is a binary field, with the + operation equivalent to modulo-2 addition, or the binary XOR operation, and the * operation equivalent to modulo-2 multiplication, or the Boolean AND operation. GF(q) is a field over the elements {0, 1, . . . , q−1} where q is a prime number. The field GF(q^{m}) is an extension field of GF(q), where the elements are defined as polynomials with coefficients in GF(q). GF(2^{m}) is an extension field of GF(2) where elements are polynomials with coefficients in GF(2).

A polynomial p(ξ) of degree m is primitive when the smallest positive integer n for which p(ξ) divides ξⁿ+1 is equal to n=2^{m}−1. The extension field GF(2^{m}) can be represented as a field F of polynomial elements, as follows:

GF(2^{m})=F={0, 1, α, α², . . . , α²^{^{m}}⁻¹}
where
   α is a third symbol, in addition to 1 and 0;
   p(α)=0;
   α²^{^{m}}⁻¹; and
   α²^{^{m}}⁻¹+1=0.
      For the operation * in F:

e_{*}=1

(αⁱ)⁻¹=α²^{^{m}}⁻ⁱ⁻¹

For the operation + in F:

e₊=0

−αⁱ=αⁱ

In addition to representing the elements of F as powers of α, each element in F can also be represented as a polynomial with binary coefficients:

αⁱ=a_{i,0}+a_{i,1}α+a_{i,2}α²+ . . . +a_{i,m-1}α^{m-1}

Addition of elements of F is easily carried out by polynomial addition, and multiplication of elements of F is easily carried out by adding exponents of the elements expressed as powers of α.

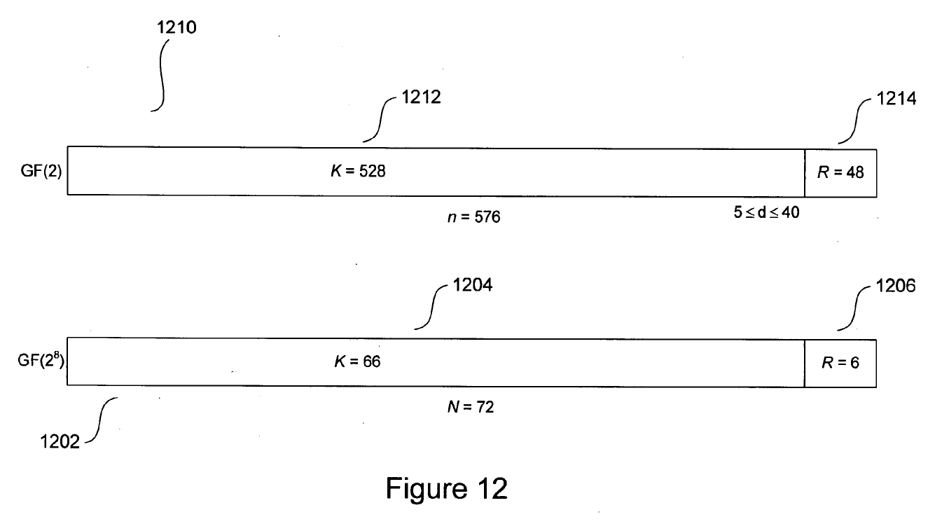

For an extension field, such as GF(2⁸), a table can be constructed for each element in GF(2⁸), each entry of which shows the powers representation of the element, the polynomial representation of the element, and a tuple of binary values comprising the coefficients of the polynomial representation of the element. FIG. 11 shows a portion of the table of elements for GF(2⁸). The first column 1102 of the table 1100 shows the powers representation of the elements of GF(2⁸), the middle column 1103 provides the polynomial representation for the elements, and the final column 1104 shows the 8-bit binary-coefficient-tuple representation of each element. Additional tables can be constructed for multiplication and addition operations. Thus, the field GF(2⁸) can be expressed as a set of 256 elements, each element an 8-bit tuple, with multiplication, addition, and subtraction operations specified by tables based on operations performed on the underlying polynomials. It is important to note that the multiplication, subtraction, and addition operations for the 8-bit element of GF(2⁸) are not equivalent to familiar binary arithmetic operations supported by electronic computers. As one example, in binary arithmetic:

00100000+10111000=11011000

but in GF(2⁸) addition:

α²=00100000=α²

α⁸=10111000=1+α²+α³+α⁴

α²+α⁸=α¹⁹³=1+α³+α⁴=10011000

The example of GF(2⁸) is provided, because, in one disclosed embodiment of the present invention, a composite code over GF(2⁸) is constructed from two component codes over GF(2⁸). Each symbol in a codeword can be viewed as an 8-bit tuple that represents an element of GF(2⁸). Note that there are 256 elements in GF(2⁸). Thus, every possible 8-bit tuple is an element of GF(2⁸). In general, for encoding and decoding purposes, information bytes are considered to be symbols in GF(2⁸), but prior to encoding and following decoding, the information bytes are viewed as standard binary-encoded bytes. In the following discussion of the present invention, example codes over GF(2⁸) are discussed, but, the methods of the present invention can be applied to creation of composite codes over any field GF(q). It turns out, for computing efficiency, composite codes over GF(2^{m}) are desirable, for efficiency in symbol representation and efficiency in computational operations.

### Embodiments of the Present Invention

The present invention is directed to a family of composite error-correcting codes that are constructed using at least two component codes and a function ƒ(), described below, that maps symbols of a field over which the composite code is defined to other symbols of the field. In the following discussion, one particular composite code from the family of composite codes that represent embodiments of the present invention is discussed. The discussed composite code is a code over 8-bit symbols of the extension field GF(2⁸). However, composite codes can be analogously constructed for symbols of an arbitrary field GF(q) or GF(q^{m}), using component codes constructed for symbols of the arbitrary field.

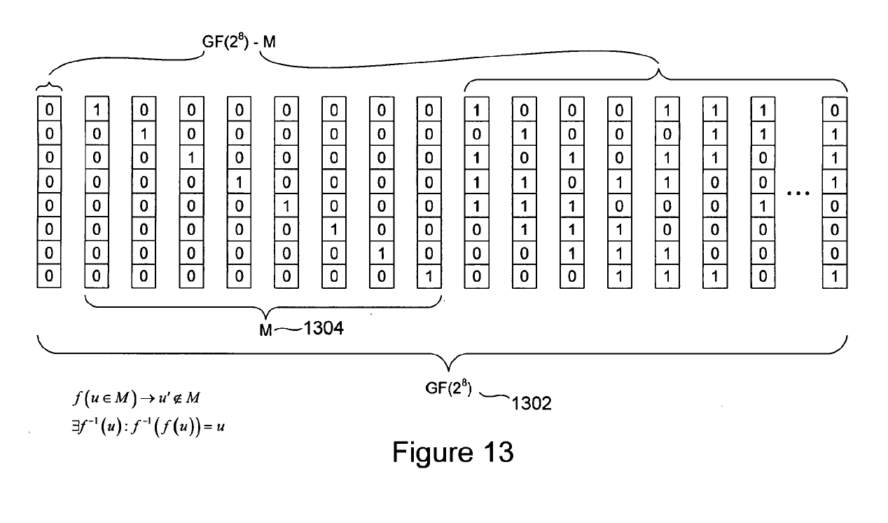

FIG. 12 illustrates the basic characteristics of a composite code that represents one embodiment of the present invention. The composite code is constructed over GF(2⁸) and produces codewords of length N=72, where N is the length, in 8-bit symbols. An exemplary codeword 1202 is shown in FIG. 12. The codeword contains K=66 information symbols and R=6 parity-check symbols. The minimum distance between codewords is D=5 symbols. The composite code can also be viewed as a code over GF(2). An exemplary codeword of the composite code over GF(2) 1210 is also shown in FIG. 12. When viewed as a code over GF(2), each codeword has n=576 bits of which k=528 bits 1212 are information bits and r=48 bits 1214 are parity-check bits. The minimum distance between codewords is in the range 5≦d≦40, depending on the nature of the particular component codes used to construct the code. A linear block code having the characteristics N=72, K=66, and D=5 would be expected to be able to detect and correct (D−1)/2=2 symbol errors or 4 symbol erasures. However, the composite code that represents an embodiment of the present invention can correct a larger number of symbol errors when they occur in bursts, a larger number of erasures, and a number of symbol errors and bit errors in addition to error bursts and erasures.

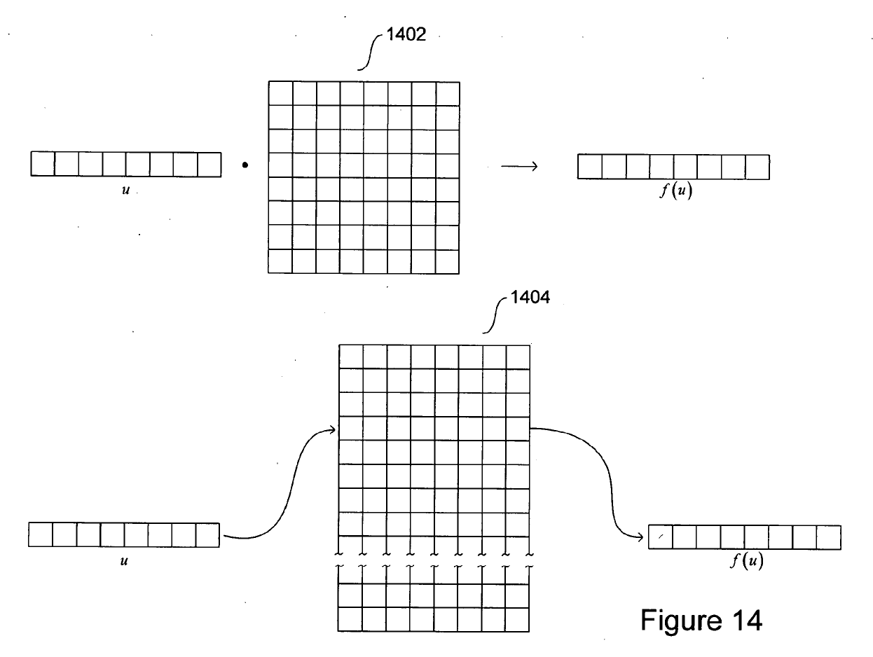

Coding and decoding methods for the composite code that represents one embodiment of the present invention relies on a symbol-to-symbol mapping function ƒ(). FIG. 13 illustrates the characteristics of the symbol-to-symbol mapping function ƒ() used in embodiments of the present invention. In FIG. 13, a sequence of 256 8-bit symbols representing the 256 elements of GF(2⁸) 1302 is partially displayed. The second through ninth symbols of GF(2⁸), referred to as the set “M,” 1304 include those symbols with 8-bit-tuple representations that each includes only a single bit with bit value “1.” These 8-bit vectors in the set M correspond to GF(2⁸) elements {1, α¹, α², . . . , α⁷} in the representation of GF(2⁸) shown in FIG. 11. Any function ƒ() that maps symbols of GF(2⁸) to other symbols of GF(2⁸) can be employed for coding and decoding of the composite code that represents an embodiment of the present invention, providing that the function ƒ() is linear, has a strict inverse function ƒ, and maps any symbol of the set M to a symbol of GF(2⁸) that is not in the set M:

ƒ(u∈M)→u′∉M

∃ƒ⁻¹(u):ƒ⁻¹(ƒ(u))=u

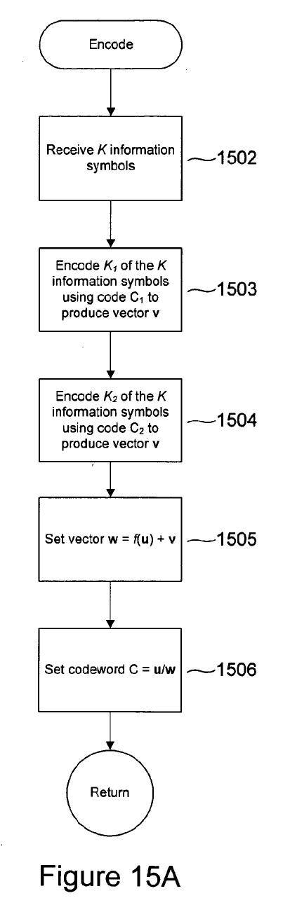

FIG. 14 shows two different implementations of the symbol-to-symbol mapping function ƒ(). In one implementation, ƒ(u) may be implemented as multiplication of a bit-vector representation of symbol u by an m×m matrix 1402, where m is the m of the binary extension field GF(2^{m}) over which the code is constructed, in the current case, 8. In an alternative embodiment, a lookup table 1404 can be prepared to provide ƒ(u) values for each possible symbol u. In the case of GF(2⁸) symbols, the symbol represented by the bit-vector u can be used as a numeric byte value to index the lookup table.

In alternative embodiments, the mapping function ƒ() may be a different function. In general, the purpose of ƒ() is to map certain types of error-word symbols to alternative symbol values, to allow the occurrence of errors of that type to be assigned either to an estimated C₂ codeword or to a C₁ codeword extracted from a composite-code codeword during decoding. All embodiments of the present invention employ a non-identity mapping function ƒ().

The function ƒ() may be applied to symbols, as discussed above, or may be applied to a vector of symbols. For example, the function ƒ() may be applied to an entire codeword u to produce a modified codeword ƒ(u), with the symbol function ƒ() applied to each symbol of the codeword to generate each corresponding symbol of the modified codeword.

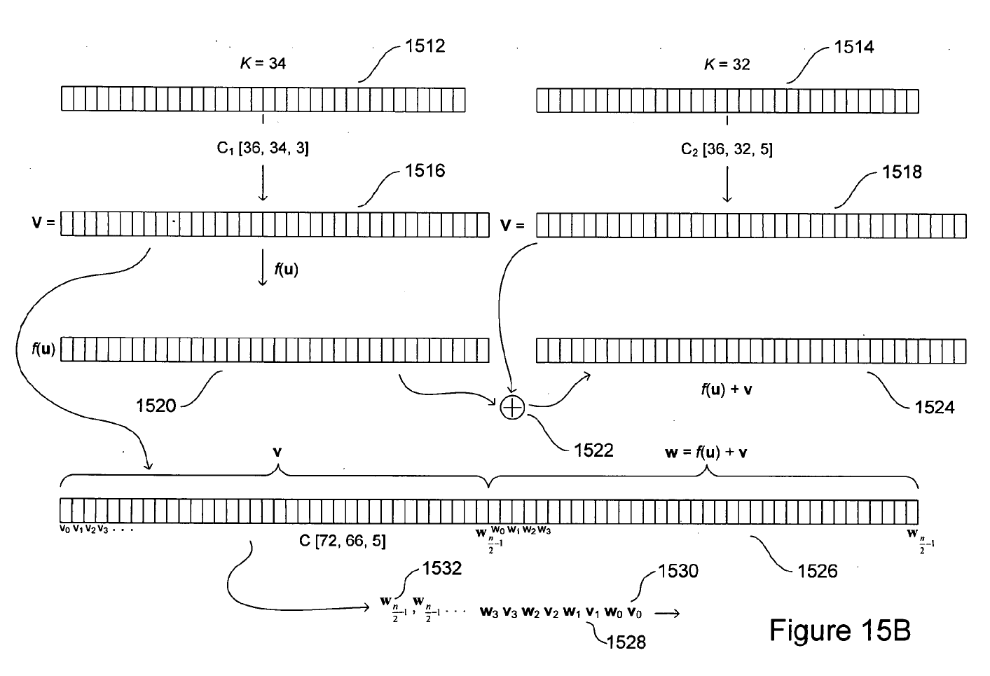

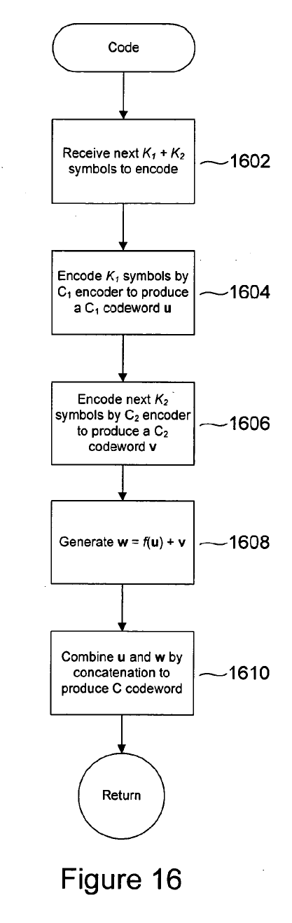

FIG. 15A provides a high-level control-flow diagram for encoding of information bits into a composite-code codeword according to one embodiment of the present invention. In step 1502, K₁ information symbols are received. In step 1503, K₁ information symbols are encoded by a first component code C₁ encoder to produce a C₁ codeword u of length N₁ symbols. In step 1504, K₂ information symbols are encoded by a second component code C₂ encoder to produce a codeword v of length N₂. In step 1505, a vector w of length N₂ symbols is obtained by adding a non-identity mapping of u, ƒ(u), to v. Finally, in step 1506, a composite-code-C codeword is generated by concatenating u and w together, the composite-code-C codeword having a length N=N₁+N₂ and containing K=K₁+K₂ information symbols.

FIG. 15B illustrates construction of the composite code C[72,66,5] that represents one embodiment of the present invention. As discussed above, the composite code relies on two component codes. The component codes may be Reed-Solomon codes, systematic linear-block codes defined over GF(q), binary systematic linear block codes, or other types of codes. In the disclosed embodiment, the first component code C₁ produces codewords with N₁=36, K₁=34, and D₁=3 and the second component C₂ has the characteristics N₂=36, K₂=32, and D₂=5. It is assumed that C₁ can detect and correct s1 symbol erasures and t1 symbol errors, where s1+2t1<D₁, and that C₂ can detect and correct s2 symbol erasures and t2 symbol errors, where s2+2t2<D₂. In fact, such codes are well known.

As shown in FIG. 15B, C₁ encodes K₁=34 information symbols 1512 to produce a 36-symbol C₁ codeword u 1516 and C₂ encodes K₂=32 information symbols 1514 to produce a 36-symbol C₂ codeword v 1518. These codewords are combined to create a codeword of the composite code C [72,66,5] that represents one embodiment of the present invention. Thus, K₁+K₂=32+34=66 information symbols are encoded into each 72-symbol codeword of the composite code that represents one embodiment of the present invention. Both C₁ codeword u and C₂ codeword v have N=36 symbols. The function ƒ() is applied successively to each symbol in u to produce a vector ƒ(u) 1520. The vector ƒ(u) is then added to the C₂ codeword v 1522 to produce the vector w=ƒ(u)+v 1524. Then, the codeword u 1516 is concatenated with w=ƒ(u)+v to produce an N=72 codeword 1526 of the composite code that represents one embodiment of the present invention. When the symbols of this codeword are transmitted or stored, the symbols from u and w alternate in the transmitted symbols, as shown in the sequence of transmitted symbols 1528, with symbol u₀ 1530 first transmitted and symbol

$${w}_{\frac{n}{2} - 1}$$

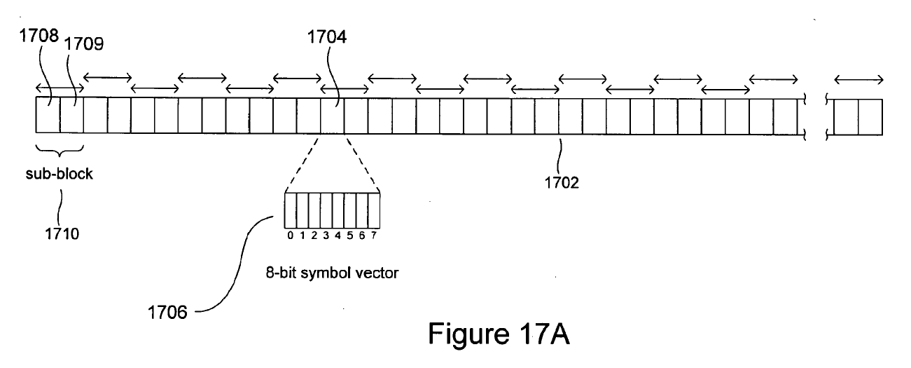

1532 last transmitted. FIG. 16 illustrates a method of encoding a composite-code codeword that can be carried out repeatedly on an input stream of information symbols to produce an output stream of composite-code codewords. In step 1602, K₁+K₂ information symbols are received for encoding. In step 1604, the first K₁ information symbols are encoded by a C₁ encoder to produce a C₁ codeword u. In step 1606, the next K₂ information symbols are encoded by a C₂ encoder to produce a C₂ codeword v. In step 1608, the vector w=ƒ(u)+v is generated from u and v using the symbol-to-symbol mapping function ƒ(). Finally, in step 1610, u and w are concatenated together to produce a composite-code codeword. The encoding of a composite-code codeword by the method illustrated in FIG. 16 can be carried out repeatedly on an input stream of information symbols to produce an output stream of composite-code codewords.

The above method of computing vector w generates a non-systematic code C. A systematic code C can be obtained by precoding. Precoding is carried out by extracting a prefix of length K₂ from ƒ(u), prefix(ƒ(u)), and creating a vector a comprising the next K₂ information symbols from the input stream. A word v′ is then produced as: v′=a−prefix(ƒ(u)). Finally, v′ is used as the K₂ information symbols that are encoded into a C₂ codeword v″, and v″ is then used to compute vector w by: w=ƒ(u)+v″.

In alternative embodiments of the present invention, composite-code codewords can be produced by other methods. The order of encoding using component codes may differ, the component codes may differ, and different symbol-to-symbol mapping functions may be employed. Alternative composite codes within the family of composite codes that represent embodiments of the present invention may have different characteristics N, K, and D, depending on the underlying code characteristic of the component codes C₁ and C₂. In alternative embodiments of the present invention, each component code may itself be generated from two or more underlying component codes.

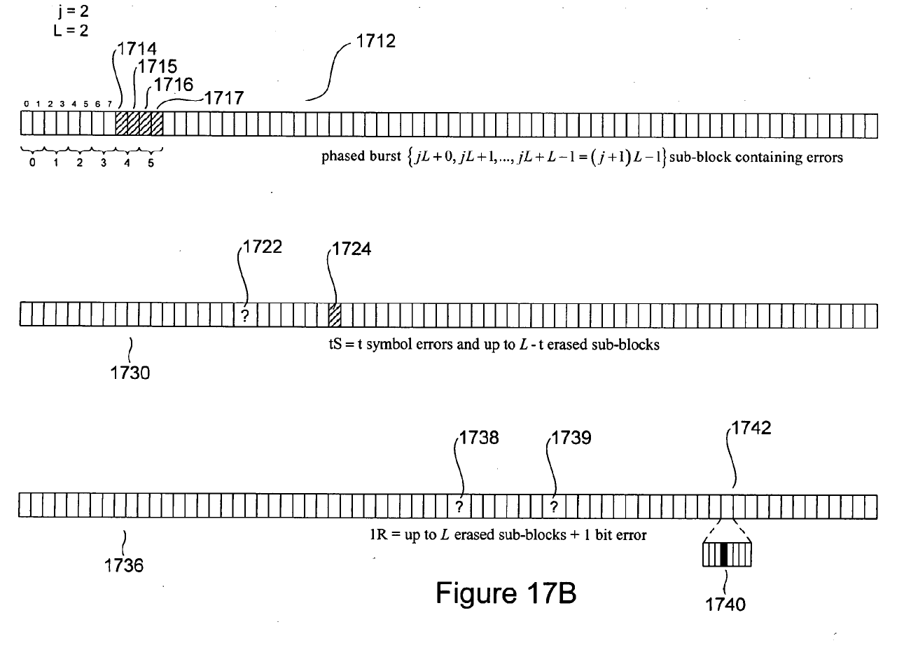

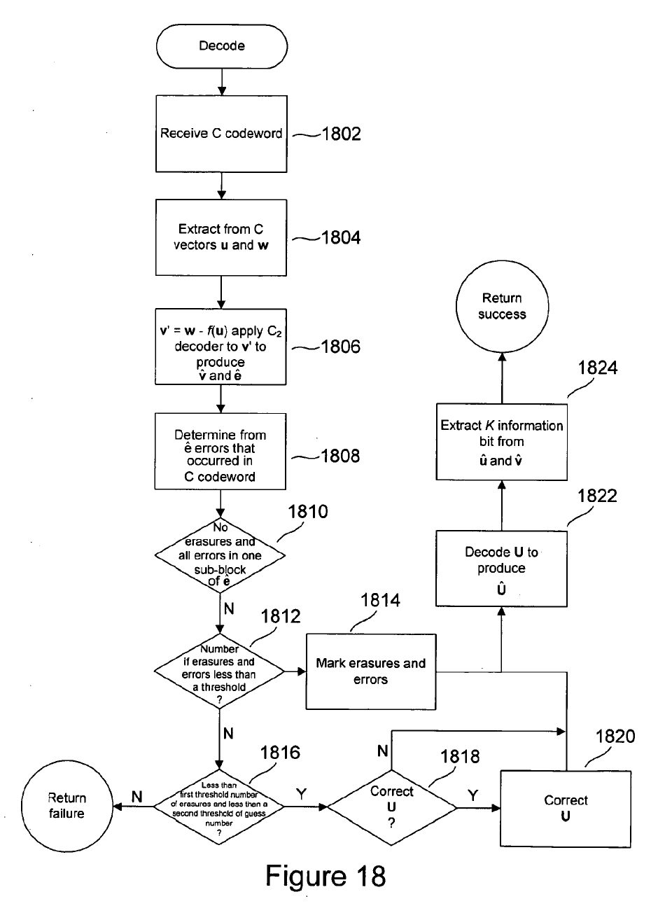

FIG. 17A illustrates the notion of a sub-block within a codeword of the composite code that represents one embodiment of the present invention. As shown in FIG. 17, a composite-code codeword 1702 can be viewed as containing 8-bit symbols, such as symbol 1704 alternatively shown expanded into an 8-bit symbol vector 1706. Each pair of symbols, such as the pair of symbols 1708-1709, can be together viewed as a sub-block 1710. Thus, a composite-code codeword can be viewed alternatively as an ordered sequence of bits, an ordered sequence of 8-bit symbols, or as ordered sequence of sub-blocks.

FIG. 17B illustrates the various different types of errors that the composite code that represents one embodiment of the present invention is designed to detect and correct. An important additional parameter of the composite code is the parameter L, a largest integer less than D/2. For various types of alternative composite codes, the value L may be fixed within the range of integers

$$1 < L < \frac{D}{2} .$$

A first type of error is referred to as a “phased-burst” error. A phased-burst error is illustrated in the first word 1712 shown in FIG. 17B. A phased-burst error is any number of corrupted symbols within a block of adjacent symbols comprising L sub-blocks. As shown in the word 1712 in FIG. 17B, four symbols, shown with cross-hatching 1714-1717 are corrupted, and all four symbols fall within a block comprising sub-blocks 4 and 5. It is assumed that a codeword containing a phased-burst error does not contain any sub-block erasures. In the case of the phased-burst error, when all four symbols within a block are corrupted, there is a small probability that the composite code may not be able to correct the errors. However, this small probability is smaller than the probability that a Reed-Solomon code with equivalent redundancy cannot correct the errors, and the composite codes of the current invention are more time efficient than Reed-Solomon codes with equivalent redundancy. When less than four symbols within the block are corrupted, all of the corrupted symbols can be corrected.

A tS error type is illustrated in the second codeword 1730 shown in FIG. 17B. The tS error type includes up to L−t sub-block erasures and t corrupted symbols. In the example shown in FIG. 17B, there is a single sub-block erasure 1722 and a single additional corrupted symbol 1724, so that t=1 and L−t=1 erased sub-block. Alternatively, there may be two erased sub-blocks and no additional corrupted symbols or two corrupted symbols and no additional erased sub-blocks. A third type of error condition to which the composite codes of the present invention are directed are 1R errors in which up to L sub-blocks are erased and one additional 1-bit error has occurred. The third codeword 1736 in FIG. 17B illustrates a 1R error in which two sub-blocks 1738-1739 are erased and a single-bit error 1740 occurs in symbol 1742.

One motivation for development of the composite codes that represent embodiments of the present invention is for error correction of a newly developed type of electronic memory. Because of the construction of this memory, the majority of expected errors include phased-burst errors, tS-type errors, and 1R-type errors. Error correction is carried out in hardware in these electronic-memory systems, and therefore the error correction component represents a significant design and manufacturing overhead. For this reason, designers and manufacturers wish to use as efficient a code as possible for detecting and correcting the expected phased-burst, tS, and 1R errors. The composite codes that represent embodiments of the present invention successfully detect and correct these expected error types using less parity-check symbols than would be needed by a conventional Reed-Solomon code for an equal number of information symbols.

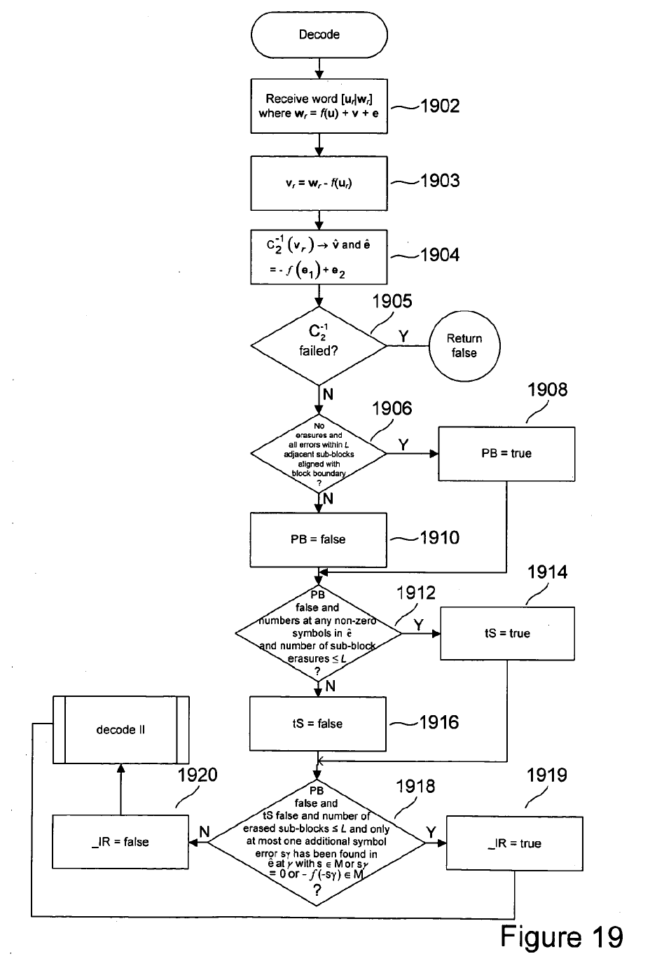

FIG. 18 provides a high-level control-flow diagram for decoding of a composite code that represents one embodiment of the present invention. In step 1802, a composite-code-C codeword of length N, containing K information symbols, is received. In steps 1804-1806, a component-code-C₁ codeword u of length N₁ containing K₁ information symbols and a modified component-code-C₂ codeword of length N₂, w=v+ƒ(u), generated, during encoding, from a component-code-C₂ codeword v containing K₂ information symbols, where K=K₁+K₂ and N=N₁+N₂, and a non-identity mapping function, ƒ(), are extracted from the composite-code-C codeword and an estimated component-code-C₂ codeword \hat{v} and an estimated error word ê are generated from the modified component-code-C₂ codeword by applying a C₂ decoder to the modified component-code-C₂ codeword. In step 1808, which of a number of types of expected errors occurred subsequent to encoding of the composite-code-C codeword is determined from the error word ê. When more than a first threshold number of erasures and erasures have occurred, but less than a second threshold number of errors have occurred, as determined in step 1816, the determined errors are assigned to either the component-code-C₁ codeword or to the modified component-code-C₂ codeword, and when assigned to the component-code-C₁ codeword, are corrected in steps 1818 and 1820. Other error and erasure occurrences are noted, in steps 1810, 1812, and 1814. In step 1822, an estimated component-code-C₂ codeword û is obtained by applying a C₁ decoder to the estimated component-code-C₁ codeword û. Finally, in step 1824, K₁ information symbols are extracted from the estimated component-code-C₂ codeword û and K₂ information symbols are extracted from the estimated component-code-C₂ codeword \hat{v} to produce K extracted information symbols.

Next, decoding of a received composite-code codeword is discussed.

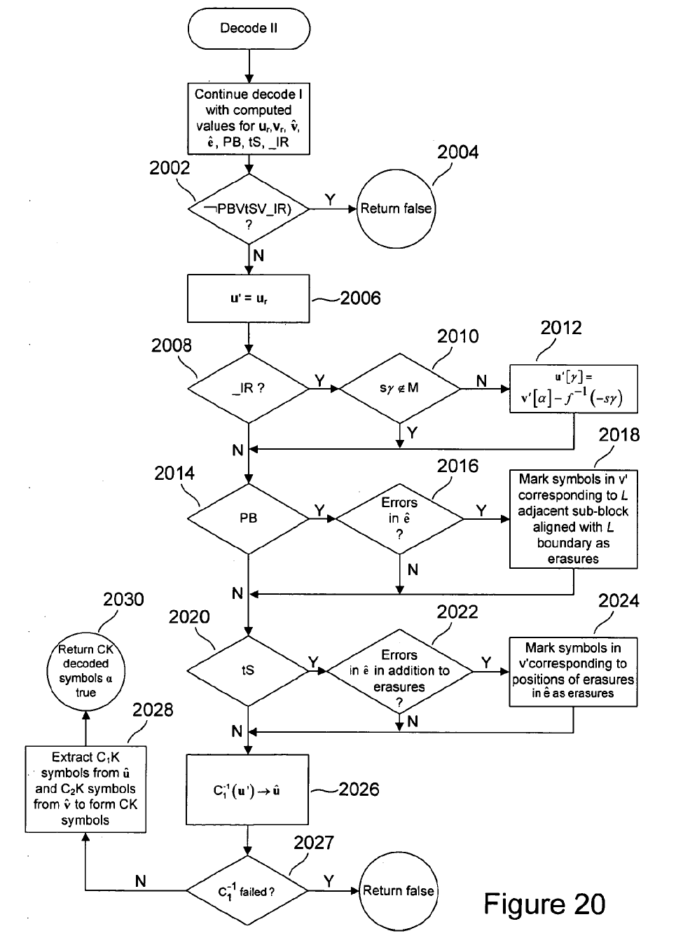

FIGS. 19-20 provide a control-flow diagram that illustrates one embodiment of the decoding process for composite codes that represent embodiments of the present invention. First, in step 1902, a composite-code C codeword is received. The received word can be viewed as two parts:

[uᵣ|wᵣ]

where uᵣ is the received u, or u+eᵢ

wᵣ is the received w, or f(u)+v+e₂

Next, in step 1903, the addition of ƒ(u) to v or v″ during encoding is reversed by:

vᵣ=−ƒ(uᵣ)+wᵣ

Next, in step 1904, the computed word vᵣ is decoded using a C₂ decoder to produce estimated codeword \hat{v} and estimated error word ê:

C₂⁻¹(vᵣ)→\hat{v} and \hat{e}
where ê=−ƒ(e₁)+e₂
   where the function-like symbol C₂⁻¹() represents decoding by a decoder for component code C_{2.}

If the C₂ decoding of vᵣ fails, as determined in step 1905, decoding of the composite-code codeword fails. Next, in a series of conditional steps, Boolean flags representing phased-burst (“PB”), tS, and 1R errors are set to indicate whether or not these types of errors appear to have occurred within the received word. Note that the notation “_{—}1R” is used for the 1R flag, below, to be consistent with later-discussed pseudocode. It should be noted that the presence of erased sub-blocks is generally indicated by a separate, out-of-band erasure indication that is not part of the received word. When no erasures have occurred and when all symbol errors have occurred within L adjacent sub-blocks lined with a block boundary, as determined in step 1906 and as discussed above with reference to FIG. 17B, then the flag PB is set TRUE in step 1908. Otherwise the flag PB is set to FALSE, in step 1910. When the flag PB contains the value FALSE and when the number of erased sub-blocks and the number of any additional non-zero symbols in the estimated error vector ê sum to a value less than or equal to L, as determined in step 1912, then the flag tS is set TRUE in step 1914. Otherwise the flag tS is set to be FALSE in step 1916. When both PB and tS contain the Boolean value FALSE, and when the number of erased sub-blocks is less than or equal to L and at most only one additional 1-bit symbol error has been found in the error vector ê, as determined in step 1917B, then the flag_{—}1R is set TRUE in step 1919. Otherwise the flag_{—}1R is set to be FALSE in step 1920. A 1-bit error is detected when a non-zero symbol s in the estimated error vector ê is either an element of the set M or −s is mapped to the set M by the symbol-to-symbol function ƒ⁻¹( ) alternatively expressed as:

S∈M or ƒ⁻¹(−s)∈M

Thus, ƒ() maps a single-bit error that occurs in u, to a symbol with more than two bits with bit value “1,” so that a single-bit error in u, can be distinguished from a single-bit error in vᵣ. Coding resumes in the flow-control diagram of FIG. 20. If none of the three Boolean flags PB, tS, and _{—}1R are set to TRUE, as determined in step 2002, then the decoder returns a FALSE value in step 2004. Otherwise, vector u is set to the first half of the received C codeword uᵣ in step 2006. If the flag_{—}1R is set to TRUE, as determined in step 2008, then if a single non-zero symbol s_{γ} is found in the estimated error vector ê at position γ and s_{γ} is not an element of the set M, as determined in step 2010, the symbol at the same position γ in u′ is replaced with the original symbol from which the inversely mapped negative error symbol is subtracted by GF(2⁸) subtraction in step 2012. Steps 2008, 2010, and 2012 allow for detection of a single-bit error in addition to L sub-block erasures. When the non-zero ê symbol s_{γ} is an element of M, then the single-bit error occurred in the latter half of the received word, or, in other words, in vᵣ. However, when s_{γ} can be mapped to M by F⁻¹(−s_{γ}), the single-bit error occurred in the first portion of the C codeword. In that case, the error is corrected in step 2012. Next, if the Boolean flag PB contains the value TRUE, as determined in step 2014, and if there are non-zero symbols in ê, as determined in step 2016, then the symbols in the block containing the errors are marked as erased in step 2018. If the flag tS contains the Boolean value TRUE, as determined in step 2020, and if there are any non-zero symbols in ê outside of any detected erasures, as determined in step 2022, then those additional symbol errors are marked as erasures in step 2024. In step 2026, a C₁ decoder is applied to u′ to produce the estimated original vector û. If the C₁ decoder fails, as determined in step 2027, composite-code decoding fails. Otherwise, in step 2028, K₁ symbols are extracted from u and K₂ symbols are extracted from \hat{v} that together form a sequence of K decoded information symbols that are returned in step 2030. As in the case of step 1904, should the C₁ decoder fail, in step 2026, then decoding fails.

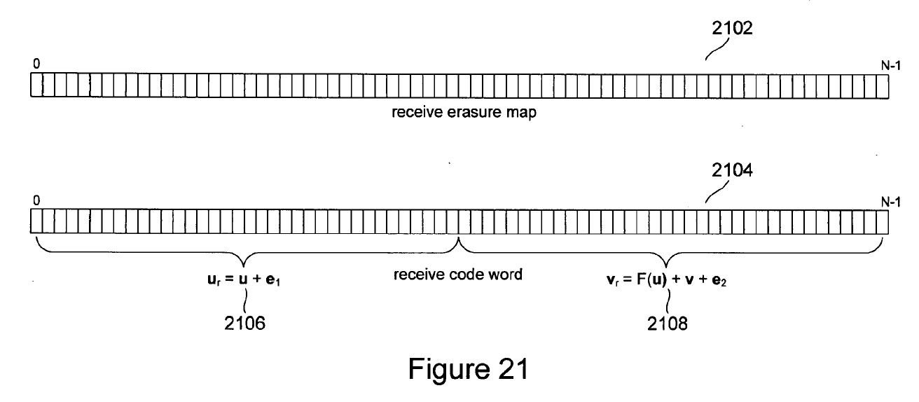

Next, a C++-like pseudocode implementation of a decoding method for decoding the above-described composite code that represents one embodiment of the present invention is provided. FIG. 21 illustrates the information received for each step of a decoding method for the composite code that represents one embodiment of the present invention. Received information includes an erasure map 2102 with a single bit for each symbol in the codeword indicating whether or not the symbol has been erased. The received information includes an erasure map 2102 that includes a bit flag for each symbol of a received word indicating whether or not the symbol has been erased, and a received word 2104 that, as discussed above, includes a first portion 2106 uᵣ which equals u+e₁, although u and e₁ are not known, and a second part 2108 vᵣ which equals F(u)+v+e₂, although u, v, and e₂ are not known.

The pseudocode implementation first includes a number of constant integer declarations:

```
  1 const int C1K = 34;
  2 const int C2K = 32;
  3 const int CK = C1K + C2K;
  4 const int C1R = 2;
  5 const int C2R = 4;
  6 const int CR = C1R + C2R;
  7 const int C1D = 3;
  7 const int C2D = 5;
  8 const int CD = 2 * C1D > C2D ? C2D : 2 * C1D;
  9 const int N = CR + CK;
10 const int L = floor ((CD−1) / 2);
11 const int symPSubBlk = 2;
12 const int Nsub = N / symPSubBlk;
13 const int N2 = N / 2;
14 const int blkPlus = N2 / symPSubBlk;
15 const int b = 8;
```

These constants include the basic parameters for composite code C and component codes C1 and C2, discussed above, including: (1) C1K, C2K, and CK, the number of information symbols in the codewords of C1, C2, and C, respectively; (2) C1R, C2R, and CR, the number of parity-check symbols in codewords of C1, C2, and C, respectively; (3) the minimum distance between codewords C1D, C2D, and CD for codewords of C1, C2, and C, respectively; (4) a constant N, the number of symbols in a codeword of the composite code C; (5) the number L, equal to the largest integer less than (CD-1)/2 in the disclosed implementation, as discussed above; (6) N2, the number of symbols in codewords of component code C1 and C2, where N2=N/2; symPSubBlk. the number of symbols per sub-block; (7) blkPlus, that, when added to the sub-block index of a block in a first portion of a composite codeword, generates the sub-block index of the corresponding sub-block of a second portion of the composite codeword; and (8) a constant b, the number of bits in a symbol, or, equivalently, a number equal to m in the expression GF(2^{m}) for the field over which the composite code C is constructed.

Next, type definitions are provided: (1) for a codeword symbol; (2) C, C1, and C2 codewords; and (3) erasure maps for C, C1, and C2 codewords:

1 typedef unsigned char symbol; // b <= 8 only
2 typedef symbol C_WORD[N];
3 typedef symbol C1_WORD[N2];
4 typedef symbol C2_WORD[N2];
5 typedef bool C_ERASURE_WORD[N];
6 typedef bool C1_ERASURE_WORD[N2];
7 typedef bool C2_ERASURE_WORD[N2];

It should be noted that the C++ type “unsigned char” can only be used to represent a symbol when the constant b is less than or equal to 8. When b=8, the unsigned-char data type, also referred to as a “byte,” is exactly the size needed to represent each symbol expressed as a tuple of binary coefficients, and thus GF(2⁸) is a most convenient field over which to construct a code, for computational efficiency.

Next, a declaration is provided for the set M which includes all symbols with 8-bit-tuple representations that include only a single bit with the bit value “1.” This declaration employs the fact that the tuples in set M correspond to bytes, in normal binary byte-value representations, to powers of two:

1 const symbol M[b] = {1, 2, 4, 8, 16, 32, 64, 128}; // elements of GF(2\hat{ }b) with a

// single-bit tuple representation

Next, declarations for five functions are provided:

1 bool C1(C1_WORD c1Word, C1_ERASURE_WORD erasures,

| | |
|---|---|
| 2 | C1_WORD decodedC1Word, C1_WORD errors); |

3 bool C2(C2_WORD c2Word, C2_ERASURE_WORD erasures,

| | |
|---|---|
| 4 | C2_WORD decodedC2Word, C2_WORD errors); |

5 symbol f(symbol a);
6 symbol fInverse(symbol a);
7 symbol GF2bSubtraction(symbol y, symbol z);

The first two functions are decoders for component codes C1 and C2. These two functions receive a codeword and erasure map and return a decoded codeword and an error word, as described above. The function ƒ() and the function ƒ⁻¹(), discussed above, are declared on lines 5 and 6 of the above code block. Finally, on line 7, a GF(2⁸) subtraction function for subtracting a GF(2⁸) symbol z from a GF(2⁸) symbol y is provided. As discussed above, it is assumed that component codes C1 and C2 exist, and that encoders and decoders are available for these component codes. No implementations are provided for the above five functions, as the decoder implementations depend on the particular component codes selected for use in constructing a composite code, because the functions ƒ() and Hare straightforwardly implemented, the implementations depending on the field over which the composite code is defined, and because GF(2^{b}) subtraction is well known.

Next, a number of class declarations are provided. First, three classes that represent an input symbol stream, an input erasure stream, and an output symbol stream are provided:

| 1 class symbolStream | |
|---|---|
| 2 { | |
| 3 | public: |

| | |
|---|---|
| 4 | bool start( ); |
| 5 | bool getNext(int num, symbol* buffer); |

| 6 }; | |
|---|---|
| 1 class erasureStream | |
| 2 { | |
| 3 | public: |

| | |
|---|---|
| 4 | bool start( ); |
| 5 | bool getNext(int num, bool* buffer); |

| 6 }; | |
|---|---|
| 1 class outputStream | |
| 2 { | |
| 3 | public: |

| | |
|---|---|
| 4 | bool start( ); |
| 5 | void outputNext(int num, symbol* buffer); |
| 6 | void finish( ); |

7 };

The various streams can be started and then accessed in order to input or output specified numbers of symbols. Implementations are not provided for these classes, since stream input and output is both well known, operating-system dependent, and possibly hardware-platform dependent.

Next, a class declaration for a class “C-decoder” is provided:

```
  1 class C_decoder
  2 {
```

| | |
|---|---|
| 3 | private: |

| | |
|---|---|
| 4 | symbolStream s; |
| 5 | erasureStream Er; |
| 6 | outputStream out; |

7

| | |
|---|---|
| 8 | void deInterleave(C_WORD c, C_ERASURE_WORD er); |
| 9 | bool decodeNextBlock(C_WORD c, C_ERASURE_WORD er, |

| | |
|---|---|
| 10 | symbol* buffer); |

11

| | |
|---|---|
| 12 | public: |

| | |
|---|---|
| 13 | bool decode( ); |

14 };

The class “C decoder” includes three private data members s, Er, and out that represent instances of the symbol stream, erasure stream, and output stream classes, respectively. The class “C_decoder” includes two private function members, declared on lines 8-10. The first private function member, “deInterleave,” transforms n symbols received from an input stream into a C codeword by deinterleaving the symbols that are interleaved, as discussed with reference to FIG. 15 (specifically 1518 in FIG. 15). The private function member “decodeNextBlock” receives a C codeword and a corresponding erasure map and outputs K decoded information symbols to an output stream. The single public function member “decode,” declared on line 13, continuously decodes symbols from an input stream and outputs corresponding decoded information symbols to an output stream.

Implementation of the function member “decode” is next provided:

| 1 bool C_decoder::decode( ) | |
|---|---|
| 2 { | |
| 3 | s.start( ); |
| 4 | Er.start( ); |
| 5 | out.start( ); |
| 6 | C_WORD c; |
| 7 | C_ERASURE_WORD er; |
| 8 | symbol buffer[CK]; |
| 9 | |
| 10 | while (s.getNext(N, c) && Er.getNext(N, er)) |
| 11 | { |

| | |
|---|---|
| 12 | deInterleave (c, er); |
| 13 | if (!decodeNextBlock(c, er, buffer)) return false; |
| 14 | out.outputNext(CK, buffer); |

| | |
|---|---|
| 15 | } |
| 16 | return (true); |

17 };

In the while-loop of lines 10-15, the function member “decode” extracts a next codeword and corresponding erasure map from the input streams c and Er, deinterleaves the input symbols on line 12, decodes the codeword on line 13, and outputs corresponding decoded information symbols on line 14. This loop continues until either decoding fails, on line 13, or until there are no additional coded symbols available from the information stream, as determined on line 10.

Next, an implementation of the function member “decodeNextBlock” is provided:

1 bool C_decoder::decodeNextBlock(C_WORD c, C_ERASURE_WORD er,

| | |
|---|---|
| 2 | symbol* buffer) |

3 {

| | |
|---|---|
| 4 | symbol* ur = &(c[0]); |
| 5 | symbol* wr = &(c[N2]); |

6

| | |
|---|---|
| 7 | bool* er1 = &(er[0]); |
| 8 | bool* er2 = &(er[N2]); |

9

| | |
|---|---|
| 10 | C1_WORD uHat, uPrime, e1Hat; |
| 11 | C2_WORD vHat, vr, e2Hat; |

12

| | |
|---|---|
| 13 | bool PB, tS, _1R, erased; |

14

| | |
|---|---|
| 15 | symbol gamma; |

16

| | |
|---|---|
| 17 | int i, j, blkIndex, gammaIndex; |
| 18 | int erasures[L]; |
| 19 | int numErasures = 0; |
| 20 | int nonZeroSymbols[L]; |
| 21 | int numNonZeroSymbols = 0; |

22

| | |
|---|---|
| 23 | for (i = 0; i < N2; i++) |

| | |
|---|---|
| 24 | vr[i] = −f(ur[i]) + wr[i]; //vr = v + −f(e1) + e2 |

25

| | |
|---|---|
| 26 | if (!C2(vr, er2, vHat, e2Hat)) return false; |

27

| | |
|---|---|
| 28 | for (i = 0; i < N; i++) |
| 29 | { |

| | |
|---|---|
| 30 | if (er[i]) |
| 31 | { |

| | |
|---|---|
| 32 | blkIndex = (i / symPSubBlk) * symPSubBlk; |
| 33 | if ((i != blkIndex) && er[blkIndex]) continue; |
| 34 | if (numErasures == L) return false; |
| 35 | else erasures[numErasures++] = blkIndex; |

| | |
|---|---|
| 36 | } |

| | |
|---|---|
| 37 | } |

38

| | |
|---|---|
| 39 | for (i = 0; i < N2; i++) |
| 40 | { |

| | |
|---|---|
| 41 | erased = false; |
| 42 | blkIndex = (i / symPSubBlk) * symPSubBlk; |
| 43 | for (j = 0; j < numErasures; j++) |
| 44 | { |

| | |
|---|---|
| 45 | if (erasures[j] == blkIndex ∥ erasures[j] == blkIndex + blkPlus) |

| | |
|---|---|
| 46 | erased = true; break; |

| | |
|---|---|
| 47 | } |
| 48 | if (erased) |

| | |
|---|---|
| 49 | i = ((blkIndex + 1) * symPSubBlk) − 1; |

| | |
|---|---|
| 50 | else |

| | |
|---|---|
| 51 | { |

| | |
|---|---|
| 52 | if (e2Hat[i] != 0) |
| 53 | { |

| | |
|---|---|
| 54 | if (numNonZeroSymbols == L) return false; |
| 55 | else nonZeroSymbols[numNonZeroSymbols++] = i; |

| | |
|---|---|
| 56 | } |

| | |
|---|---|
| 57 | } |

| | |
|---|---|
| 58 | } |

59

| | |
|---|---|
| 60 | if (numErasures == 0) |
| 61 | { |

| | |
|---|---|
| 62 | if (numNonZeroSymbols == 0) PB = true; |

| | |
|---|---|
| 63 | else if (nonZeroSymbols[numNonZeroSymbols − 1] - |

| | |
|---|---|
| 64 | nonZeroSymbols[0] <= L) |

| | |
|---|---|
| 65 | PB = true; |

| | |
|---|---|
| 66 | else PB = false; |

| | |
|---|---|
| 67 | } |

68

| | |
|---|---|
| 69 | if (!PB && numNonZeroSymbols + numErasures < L) tS = true; |
| 70 | else tS = false; |

71

| | | |
|---|---|---|
| 72 | if (!PB & | & !tS && numNonZeroSymbols == 1) |
| 73 | { | |

| | |
|---|---|
| 74 | gammaIndex = nonZeroSymbols[0]; |
| 75 | gamma = 0; |
| 76 | if (e2Hat[gammaIndex] == 0) _1R = true; |
| 77 | else |
| 78 | { |

| | |
|---|---|
| 79 | _1R = false; |
| 80 | for (i = 0; i < b; i++) |
| 81 | { |

| | |
|---|---|
| 82 | if ((e2Hat[gammaIndex] == M[i])) |
| 83 | { |

| | |
|---|---|
| 84 | _1R = true; |
| 85 | break; |

| | |
|---|---|
| 86 | } |
| 87 | gamma = fInverse(-e2Hat[gammaIndex]); |
| 88 | if (gamma = M[i]) |
| 89 | { |

| | |
|---|---|
| 90 | _1R = true; |
| 91 | break; |

| | |
|---|---|
| 92 | } |
| 93 | gamma = 0; |

| | |
|---|---|
| 94 | } |

| | |
|---|---|
| 95 | } |

| | |
|---|---|
| 96 | } |

97

| | | |
|---|---|---|
| 98 | if (!PB & | & !tS && !_1R) return false; |

99

| | |
|---|---|
| 100 | for (i = 0; i < N2; i++) uPrime[i] = ur[i]; |

101

| | |
|---|---|
| 102 | if (PB) |

| | |
|---|---|
| 103 | for (i = 0; i < numErasures; i++) |

| | |
|---|---|
| 104 | for (j = 0; j < symPSubBlk; j++) |

| | |
|---|---|
| 105 | er1[i +j] = true; |

106

| | |
|---|---|
| 107 | if (tS) |

| | |
|---|---|
| 108 | for (i = 0; i < numNonZeroSymbols; i++) |

| | |
|---|---|
| 109 | er1[nonZeroSymbols[i]] = true; |

110

| | |
|---|---|
| 111 | uPrime[i] = GF2bSubtraction(uPrime[i], gamma); |

112

| | |
|---|---|
| 113 | if (!C1(uPrime, er1, uHat, e1Hat)) return false; |

114

| | |
|---|---|
| 115 | for (i = 0; i < C1K; i++) *buffer++ = uPrime[i]; |
| 116 | for (i = 0; i < C2K; i++) *buffer++ = vHat[i]; |
| 117 | return true; |

118 }

The function member “decodeNextBlock” receives a composite-code codeword c, corresponding erasure map er, and a symbol buffer in which to place the decoded information symbols corresponding to received word c. On lines 4-5 symbol pointers ur and wr are declared to point to the first and second halves of the received word C. These symbol pointers ur and wr correspond to uᵣ and wᵣ in FIG. 21. Similarly, on lines 7-8, erasure-map pointers er1 and er2 are declared to point to the portions of the received erasure word er corresponding to the first half and the second half of the received word C, respectively.

On lines 10-21, a number of local variables are declared. These local variables have names corresponding to the notation used in the above discussions of the composite code, component codes, composite-code encoding, and composite-code decoding. For example, the variable vHat, declared on line 11, represent the estimated decoded codeword \hat{v} discussed above. The arrays “erasures” and “nonZeroSymbols,” declared on lines 18 and 20, respectively, contain the indices of erased sub-blocks and the indices of additional errors detected in the erasure map and the estimated error vector e2Hat, respectively. The use of the local variables is clarified by their use, described below, in the function member “decodeNextBlock.”

On lines 23-24, the vector “vr” is computed as vr=wr −ƒ(ur). On line 26, vr is decoded to produce \hat{v} and ê, referred in the code as “vHat” and “e2Hat,” respectively. In the for-loop of lines 28-37, indices of all erased sub-blocks are determined and stored in the array “erasures.” Note that if the number of sub-block erasures is greater than L, the decode routine fails, since only up to L erasures can be detected and corrected by the composite code implemented in the pseudocode. Note also that if the C2 decoder, invoked on line 26, fails, then decoding fails. Next, in the for-loop of lines 39-58, any errors in ê, represented by non-zero symbols, apart from any detected erased sub-blocks are noted, and the indices of the non-zero symbols corresponding to the errors are stored in the array “nonZeroSymbols.”

On lines 60-67, the Boolean flag PB is set to TRUE or FALSE, depending on whether or not a phased-burst error is detected in the codeword. PB is set to TRUE when there are no erasures and when either there are no additional error symbols or all of the error symbols occur within a single block composed of L adjacent sub-blocks. Recall that the function member “decodeNextBlock” will have already failed if there are more than L erased sub-blocks. Next, on lines 69-70, the Boolean flag tS is set to TRUE or FALSE, depending on whether or not a tS-type error is detected in the received word. The flag tS is set to TRUE when PB is FALSE and the number of erased sub-blocks added to the number of additional error symbols produces a sum less than or equal to L.

Next, on lines 72-96, the Boolean flag_{—}1R is set to TRUE or FALSE. The Boolean flag_{—}1R is set to TRUE when there is a single additional 1-bit error, or no additional errors, along with up to L erased sub-blocks. Note that decoding has already failed, on line 34, if more than L erased sub-blocks were detected. An error symbol represents a 1-bit error when either the error symbol is a member of the set M, as determined on line 81, or an inverse mapping by ƒ⁻¹() of the GF(2^{b})-additive inverse of the symbol value of the error symbol maps to M, as determined on line 88.

When all of the Boolean flags are FALSE, as determined on line 98, then decoding fails. Otherwise, uPrime is set to the first portion of the received word c on line 100. When PB is TRUE, all symbols of all sub-blocks containing errors are marked as erasures, on lines 102-105. When tS is TRUE, then all additional error symbols are marked as erasures, on lines 107-109. When a 1-bit additional error is detected in the first portion of the codeword, on line 88, then, on line 109, uPrime is altered to correct the area by subtraction of the inversely mapped inverse symbol value from uPrime, on line 111. Finally, on line 113, uPrime is decoded by the C1 decoder. If the C1 decoder fails, then decoding fails. Otherwise, the information symbols in uPrime and vHat are placed in the buffer for return to the member function “decode.”

As mentioned above, composite codes that represent embodiments of the present invention may be constructed to efficiently detect and correct specific types of error and erasure patterns and occurrences. For example, suppose that it is desired to detect and correct up to L erased sub-blocks and t additional random single-bit errors in a symbol. When L<D1 and L+2t<D2, and when a linear code C over GF(2) exists with CN equal to 2*b, dimension K′=b, and minimum codeword distance D′≧2* t+1, where C′ is defined by a parity check matrix H′=[I_{b}|−A], and where −A is invertible, then the above described composite code can be used to detect up to L=2 erased sub-blocks and t=2 additional random single-bit errors, in the case of the above-discussed composite code. Note that −A is a b×b matrix over GF(2). In this case, the symbol-to-symbol mapping function ƒ() is defined to be: θ()=uᵢ·A^{T} where uᵢ is a symbol of GF(2⁸), in the case of the above-discussed composite code. The condition “L<D1 and L+2t<D2” ensures that the C2 decoder can successfully decode vᵣ. The condition related to linear code C ensures that ƒ() will successfully map a symbol u, with one or two random-bit errors to a different symbol distinguishable from a one-or-two-random-bit-error corrupted symbol, so that the composite-code decoder can determine in which of the two halves of the codeword that a one-or-two-random-bit corruption occurred. In the current case, a non-zero symbol ê=−ƒ(ê_{i,1})+ê_{i,2} in the C2 error word ê can be used to generate a syndrome for C′, s=êᵢH′^{T}, and the syndrome s can then be used to select a corresponding C′ error word e′ that comprises the concatenation of ê_{i,2} and −ƒ(ê_{i,1}). Thus, a random-two-bit-error corrupted symbol in e can be attributed to the first half or the second half of a composite-code codeword.

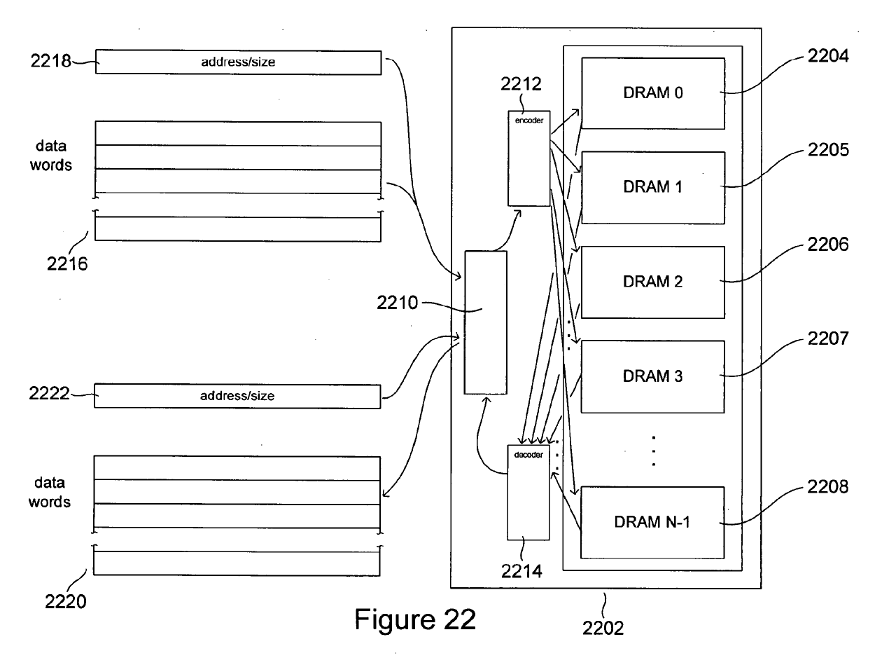

FIG. 22 shows a block diagram of a physical memory device in which embodiments of the present invention may be employed. The memory 2202 includes a bank of individual DRAM component memories 2204-2208, a bus controller and logic for receiving and transmitting data 2210, an encoder 2212 for applying a composite code to data values prior to storage in the memory, and a decoder 2214 for decoding encoded values retrieved from the memory. Memory operations include storing a block of data words 2216 identified by an address and size, in words, 2218 into the memory and retrieving a block of words 2220 identified by an address and size, in words, 2222 from the memory.

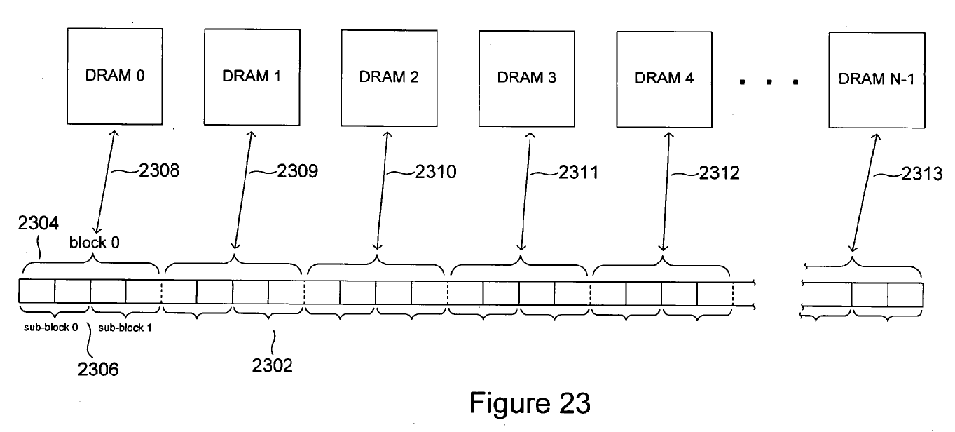

FIG. 23 illustrates mapping between codeword symbols and DRAM units in a bank of DRAM units that together comprise the electronic data storage component of the physical memory device illustrated in FIG. 22. In one embodiment, each word received for storage in the memory is encoded to a composite-code codeword 2303 by the encoder component of the memory (2212 in FIG. 22), which can be viewed as an array of blocks, such as block 2304, each block comprising a number of sub-blocks, such as sub-block 2306. Each block is mapped into a corresponding DRAM, as indicated by double-headed arrows 2308-2313 in FIG. 23. Thus, for example, a DRAM failure would result in a phased-burst error spanning a block of the codeword. The composite codes of the present invention are designed to correct the most probable failure modes of the memory. For example, the above-discussed composite code can correct for a single DRAM failure, several sub-several sub-block and symbol failures in several DRAMS. By using the composite code, the probability of a memory error, already quite low due to the low probability of a memory-component error, is substantially lowered by correcting for any of the most probable component errors.

Although the present invention has been described in terms of particular embodiments, it is not intended that the invention be limited to these embodiments. Modifications within the spirit of the invention will be apparent to those skilled in the art. For example, as discussed above, any number of different component codes may be combined to create a composite code, providing that suitable symbol-to-symbol mapping functions ƒ() can be found to map certain errors to corresponding symbols that pass through component-code encodings. The encoding and decoding methods for composite codes may be implemented in software, firmware, hardware, or a combination of two or more of software, firmware, and hardware. Software implementations may employ any of a variety of different programming languages, modular organizations, control structures, data structure, and may vary by any of many other such programming parameters. Composite codes of the present invention may be devised for efficient detection and correction of many different types of error and erasure patterns and occurrences. In alternative embodiments of the present invention, different symbol-to-symbol mapping functions may be employed to determine the location of certain types of errors in a composite-code codeword. In still alternative embodiments of the present invention, the mapping function ƒ() may map pairs of symbols to other pairs of symbols, or may map other portions of a codeword to different values.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purpose of illustration and description. They are not intended to be exhaustive or to limit the invention to the precise forms disclosed. Many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. A method for encoding K information symbols, the method comprising:
using a first component code C₁ to encode K₁ information symbols in a C₁ codeword u of length N₁ symbols;
using a second component code C₂ to encode K₂ information symbols in a C₂ codeword v of length N₂;
generating a vector w of length N₂ symbols by adding a non-identity mapping of u, ƒ(u), to v; and
generating a composite-code-C codeword by concatenating u and w together, the composite codeword of length N=N₁+N₂ containing K=K₁+K₂ information symbols.

2. The method of claim 1 wherein component codes C₁ and C₂ and composite code C are linear block codes over GF(q) containing symbols that each comprises an element of GF(q).

3. The method of claim 1 wherein component codes C₁ and C₂ and composite code C are linear block codes over GF(2⁸) containing symbols that each comprises an 8-bit element of GF(2⁸).

4. The method of claim 3 wherein:
N₁ equals 36 symbols;
K₁ equals 34 symbols;
N₂ equals 36 symbols;
K₂ equals 32 symbols;
N=72 symbols; and
K=66 symbols.

5. The method of claim 1 wherein the non-identity mapping ƒ() is applied, symbol-by-symbol, to each symbol uᵢ in vector u and maps each symbol value equal to a particular type of expected error-word symbol value to a different symbol value that can be used to subsequently identify whether or not an error of the expected type, detected on decoding of the C codeword, has occurred in u or in w.

6. The method of claim 1 wherein there is an inverse function ƒ⁻¹() such that ƒ⁻¹(ƒ(u))=u.

7. The method of claim 1 wherein the non-identity mapping ƒ() maps a symbol uᵢ, a bit-tuple representation of which includes only a single bit having binary value “1,” to a different symbol ƒ(uᵢ), a bit-tuple representation of which includes at least two bits having binary value “1.”

8. A memory device that includes an encoder that encodes words received for storage in the memory by the method of claim 1.

9. Computer instructions encoded in a computer-readable medium for encoding K information symbols by the method of claim 1.

10. A method for decoding a composite-code-C codeword of length N, containing K information symbols, to extract the K information symbols, the method comprising:
extracting, from the composite-code-C codeword, a component-code-C₁ codeword of length N₁ containing K₁ information symbols and a modified component-code-C₂ codeword of length N₂ generated, during encoding, from a component-code-C₂ codeword containing K₂ information symbols, where K=K₁+K₂ and N=N₁+N₂, and a non-identity mapping function, ƒ();
generating an estimated component-code-C₂ codeword \hat{v} and an estimated error word ê from the modified component-code-C₂ codeword by applying a C₂ decoder to the modified component-code-C₂ codeword;
determining, from the error word ê, which of a number of types of expected errors occurred subsequent to encoding of the composite-code-C codeword;
when more than a first threshold number of erasures and erasures have occurred, but less than a second threshold number of errors have occurred, assigning determined errors to either the component-code-C₁ codeword or to the modified component-code-C₂ codeword;
correcting any of the determined errors in the component-code-C₁ codeword that can be corrected based on the estimated component-code-C₂ codeword \hat{v} and an estimated error word ê;
generating an estimated component-code-C₂ codeword û by applying a C₁ decoder to the component-code-C₁ codeword; and
extracting K₁ information symbols from the estimated component-code-C₂ codeword û and K₂ information symbols from the estimated component-code-C₂ codeword \hat{v} to produce K extracted information symbols.

11. The method of claim 10 wherein component codes C₁ and C₂ and composite code C are linear block codes over GF(q) containing symbols that each comprises an element of GF(q).

12. The method of claim 10 wherein component codes C₁ and C₂ and composite code C are linear block codes over GF(2⁸) containing symbols that each comprises an 8-bit element of GF(2⁸).

13. The method of claim 12 wherein:
N₁ equals 36 symbols;
K₁ equals 34 symbols;
N₂ equals 36 symbols;
K₂ equals 32 symbols;
N=72 symbols; and
K=66 symbols.

14. The method of claim 10 wherein determining, from the error word ê, which of a number of types of expected errors occurred subsequent to encoding of the composite-code-C codeword further comprises:
considering an additionally received indication of erased symbols in the composite-code-C codeword to determine whether any of a number of different types of errors occurred in the composite-code-C codeword following encoding of the composite-code-C codeword.

15. The method of claim 10 wherein the number of different types of errors include:
a phased burst error, comprising only erroneous symbols within a threshold number of adjacent sub-blocks of symbols within the composite-code-C codeword;
a type tS error, comprising up to a threshold number of erased sub-blocks of symbols and additional erroneous symbols; and
a type 1R error, comprising up to a first threshold number of erased sub-blocks and up to a second threshold number of additional single-bit errors.

16. The method of claim 15 wherein assigning determined errors to either the component-code-C₁ codeword or to the component-code-C₂ codeword further includes:
for each non-zero symbol in the error word ê indicative of an expected type of error, assigning an error of the expected type of error to the estimated component-code-C₂ codeword \hat{v}; and
for each non-zero symbols in the error word ê, êᵢ, that can each be mapped by an inverse of a non-identity mapping ƒ(), ƒ⁻¹ (), to a symbol indicative of an expected type of error, assigning an error of the expected type of error to the component-code-C₁ codeword.

17. The method of claim 15 wherein the non-identity mapping ƒ() maps a symbol êᵢ, a bit-tuple representation of which includes only a single bit having binary value “1,” to a symbol ƒ(êᵢ), a bit-tuple representation of which includes at least two bits having binary value “1.”

18. The method of claim 15 wherein correcting any of the determined errors in the component-code-C₁ codeword that can be corrected based on the estimated component-code-C₂ codeword \hat{v} and an estimated error word ê further includes:
marking sub-blocks containing erasures as being erased in the component-code-C₁ codeword; and
correcting any symbols in the component-code-C₁ codeword corresponding to error-word symbols that can be mapped by an inverse of a non-identity mapping ƒ⁻¹() to a symbol indicative of an expected type of error.

19. A memory device that includes a decoder that decodes words retrieved from a memory component of the memory device by the method of claim 10.

20. Compute instructions encoded in a computer-readable medium for encoding K information symbols by the method of claim 10.
